(19) United States
(12) Patent Application Publication
(10) Pub. No.: US 2024/0203807 A1
(43) Pub. Date: Jun. 20, 2024

(54) FLUID-INFUSED ENCAPSULATION OF WATER-SENSITIVE MATERIALS WITH REPLENISHABLE, MULTISCALE WATER REPELLENCY

(71) Applicant: President and Fellows of Harvard College, Cambridge, MA (US)

(72) Inventors: Yanhao YU, Cambridge, MA (US); Joanna AIZENBERG, Cambridge, MA (US); Michael AIZENBERG, Boston, MA (US); Baptiste LEMAIRE, Cambridge, MA (US)

(21) Appl. No.: 17/773,145

(22) PCT Filed: Nov. 2, 2020
(86) PCT No.: PCT/US2020/058532

§ 371 Date: Apr. 29, 2022

Related U.S. Application Data
(60) Provisional application No. 62/928,846, filed on Oct. 31, 2019.

(51) Int. Cl. H01L 23/22; H01L 23/26; H01L 31/048; H10K 30/50; H10K 30/88

(52) U.S. Cl. CPC H01L 23/22; H01L 23/26; H01L 31/048; H10K 30/88; H10K 30/50

(57) ABSTRACT

In one aspect, a liquid-based encapsulation system includes an electronic material having a plurality of exposed surfaces; and an encapsulating liquid disposed over an entirety of the exposed surfaces of the electronic material to prevent diffusion of water past the encapsulating liquid and to protect the electronic material from water. In one aspect, a method of making a liquid-based encapsulation system includes providing an electronic material having a plurality of exposed surfaces; and encapsulating the electronic material with an encapsulating liquid over an entirety of the exposed surfaces of the electronic material to prevent diffusion of water past the encapsulating liquid and to protect the electronic material from water.

### RELATED APPLICATIONS

This application claims the benefit of priority to co-pending U.S. Provisional Application Ser. No. 62/928,846, filed Oct. 31, 2019, the contents of which is incorporated by reference.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF THE INVENTION

This application relates to systems for encapsulation of water-sensitive materials and devices. In particular this application relates to liquid encapsulation of electronic devices.

### BACKGROUND

Hermetic encapsulation at the material and device level is important for maintaining the operational stability of many state-of-the-art electronic systems. The development of encapsulation proceeded in parallel with the microelectronic industry. The first package was made from an alloy of nickel, cobalt, manganese and iron (trade named as Kovar) in 1936. Kovar was later combined with glass and served as the early packaging design for transistors. The first plastic encapsulation emerged on the market in the 1950s.

### SUMMARY

In one aspect, a liquid-based encapsulation system includes an electronic material having a plurality of exposed surfaces; and an encapsulating liquid disposed over an entirety of the exposed surfaces of the electronic material to prevent diffusion of water past the encapsulating liquid and to protect the electronic material from water.

In some embodiments, the liquid-based encapsulation system includes a coating material infused with the encapsulating liquid.

In some embodiments, the coating material is a polymer.

In some embodiments, the polymer is crosslinked.

In some embodiments, the polymer is selected from the group consisting of fluoropolymers, butyl rubbers, silicones, polyethylene, polystyrene, polyvinyl chloride, their copolymers with each other, and combinations thereof.

In some embodiments, the electronic material, the polymer, and the encapsulating liquid disposed within a container.

In some embodiments, the container is rigid.

In some embodiments, the container is flexible.

In some embodiments, the container is formed by the polymer.

In some embodiments, the container includes a fluid inlet.

In some embodiments, the container includes a fluid outlet.

In some embodiments, the liquid-based encapsulation system includes a pump fluidically connected to the container by an inlet and an outlet.

In some embodiments, the liquid-based encapsulation system includes a water-removal unit fluidically connected to the container by an inlet and an outlet.

In some embodiments, the encapsulating liquid includes a plurality of encapsulating liquids forming a multi-layered system.

In some embodiments, the plurality of liquids are immiscible.

In some embodiments, the plurality of liquids have different densities.

In some embodiments, the plurality of liquids have different viscosities.

In some embodiments, the liquid-based encapsulation system includes a plurality of membranes disposed between each of the plurality of encapsulating liquids.

In some embodiments, plurality of membranes include the polymer.

In some embodiments, the plurality of liquids are miscible.

In some embodiments, the plurality of liquids have the same densities.

In some embodiments, the container includes a plurality of inlets and a plurality of outlets each associated with one of the plurality of encapsulating liquids.

In some embodiments, the liquid-based encapsulation system includes a microorganism within the encapsulating liquid.

In some embodiments, the microorganism converts a contaminant into the encapsulating liquid.

In some embodiments, the microorganism converts water and carbon dioxide to a carbon oil through photosynthesis.

In some embodiments, the microorganism converts hydrogen or water and nitrogen into ammonia through a nitrogen fixation process.

In some embodiments, the liquid-based encapsulation system includes a plurality of microorganisms each within one of the plurality of encapsulating liquids.

In some embodiments, the liquid-based encapsulation system includes an inorganic semiconductor within the encapsulating liquid that removes water from the encapsulating liquid.

In some embodiments, the inorganic semiconductor splits water into hydrogen and oxygen.

In some embodiments, the encapsulating liquid forms an overlayer over the polymer.

In some embodiments, the overlayer is slippery.

In some embodiments, the overlayer is self-cleaning.

In some embodiments, the overlayer is self-healing.

In some embodiments, the overlayer is transparent.

In some embodiments, polymer confines the encapsulating liquid such that the free energy barrier for diffusion of water is increased.

In some embodiments, the encapsulating liquid is confined by an applied stress.

In some embodiments, the applied stress is a tensile stress.

In some embodiments, the applied stress is a compressive stress.

In some embodiments, applied stress is a bending stress.

In some embodiments, the polymer is cured from a mixture of a polymer precursor and the encapsulating liquid.

In some embodiments, the coating material is a porous material.

In some embodiments, the porous material has a pore size of 100 nm-10 μm.

In some embodiments, the porous material is selected from the group consisting of silica, titania, alumina, and combinations thereof.

In some embodiments, the porous material is an inverse opal.

In some embodiments, the electronic material, the porous material, and the encapsulating liquid are disposed within a container.

In some embodiments, the container is rigid.

In some embodiments, the container is flexible.

In some embodiments, the container is formed by the porous material.

In some embodiments, the container comprises a fluid inlet.

In some embodiments, the container comprises a fluid outlet.

In some embodiments, the liquid-based encapsulation system includes a pump fluidically connected to the container by an inlet and an outlet.

In some embodiments, the liquid-based encapsulation system includes a water-removal unit fluidically connected to the container by an inlet and an outlet.

In some embodiments, the encapsulating liquid includes a plurality of encapsulating liquids forming a multi-layered system.

In some embodiments, the plurality of liquids are immiscible.

In some embodiments, the plurality of liquids have different densities.

In some embodiments, the plurality of liquids have different viscosities.

In some embodiments, the liquid-based encapsulation system includes a plurality of membranes disposed between each of the plurality of encapsulating liquids.

In some embodiments, the plurality of membranes comprise the porous material.

In some embodiments, the plurality of encapsulating liquids are miscible.

In some embodiments, the plurality of encapsulating liquids have the same densities.

In some embodiments, the container includes a plurality of inlets and a plurality of outlets each associated with one of the plurality of encapsulating liquids.

In some embodiments, the liquid-based encapsulation system includes a microorganism within the encapsulating liquid.

In some embodiments, the microorganism converts a contaminant into the encapsulating liquid.

In some embodiments, the microorganism converts water and carbon dioxide to a carbon oil through photosynthesis.

In some embodiments, the microorganism converts hydrogen or water and nitrogen into ammonia through a nitrogen fixation process.

In some embodiments, the liquid-based encapsulation system includes a plurality of microorganisms each within one of the plurality of encapsulating liquids.

In some embodiments, the liquid-based encapsulation system includes an inorganic semiconductor within the encapsulating liquid that removes water from the encapsulating liquid.

In some embodiments, the inorganic semiconductor splits water into hydrogen and oxygen.

In some embodiments, the encapsulating liquid forms an overlayer over the polymer.

In some embodiments, the overlayer is slippery.

In some embodiments, the overlayer is self-cleaning.

In some embodiments, the overlayer is self-healing.

In some embodiments, the overlayer is transparent.

In some embodiments, the porous material confines the encapsulating liquid such that the free energy barrier for diffusion of water is increased.

In some embodiments, the encapsulating liquid is confined by an applied stress.

In some embodiments, the applied stress is a tensile stress.

In some embodiments, the applied stress is a compressive stress.

In some embodiments, the applied stress is a bending stress.

In some embodiments, the electronic material is disposed within a container.

In some embodiments, the container is rigid.

In some embodiments, the container is flexible.

In some embodiments, the container comprises a fluid inlet.

In some embodiments, the container comprises a fluid outlet.

In some embodiments, the liquid-based encapsulation system includes a water-sensitive dye in the encapsulating liquid.

[In some embodiments, the liquid-based encapsulation system includes a pump fluidically connected to the container by an inlet and an outlet.

In some embodiments, the liquid-based encapsulation system includes a water-removal unit fluidically connected to the container by an inlet and an outlet.

In some embodiments, the encapsulating liquid includes a plurality of encapsulating liquids forming a multi-layered encapsulation.

In some embodiments, the plurality of liquids are immiscible.

In some embodiments, the plurality of liquids have different densities.

In some embodiments, the plurality of liquids have different viscosities.

In some embodiments, the container includes a plurality of inlets and a plurality of outlets each associated with one of the plurality of encapsulating liquids.

In some embodiments, the liquid-based encapsulation system includes a microorganism within the encapsulating liquid.

In some embodiments, the microorganism converts a contaminant into the encapsulating liquid.

In some embodiments, the microorganism converts water and carbon dioxide to a carbon oil through photosynthesis.

In some embodiments, the microorganism converts hydrogen or water and nitrogen into ammonia through a nitrogen fixation process.

In some embodiments, the liquid-based encapsulation system includes a plurality of microorganisms each within one of the plurality of encapsulating liquids.

In some embodiments, the liquid-based encapsulation system includes an inorganic semiconductor within the encapsulating liquid that removes water from the encapsulating liquid.

In some embodiments, the inorganic semiconductor splits water into hydrogen and oxygen.

In some embodiments, the encapsulating liquid includes polar moieties.

In some embodiments, the encapsulating liquid is selected from a group consisting of polyfluorinated liquids, perfluorinated liquids, partially fluorinated liquids, hydrocarbons, organosilanes, silicone oils, mineral oils, plant oils, and combinations thereof.

In some embodiments, the electronic material is selected from a group consisting of perovskite, photovoltaic cells, perovskite photovoltaic cells, integrated circuits, flexible circuits, and combinations thereof.

In some embodiments, a method of replenishing an encapsulating liquid to a liquid-based encapsulation system including an electronic material and the encapsulating liquid forming an overlayer over the electronic material includes introducing additional encapsulating liquid to the liquid-based encapsulation system.

In some embodiments, introducing additional encapsulating liquid occurs at periodic intervals.

In some embodiments, introducing additional encapsulating liquid occurs continuously.

In some embodiments, introducing additional encapsulating liquid occurs when the water vapor transport rate in the encapsulating liquid exceeds 10⁻⁵ g m⁻² per day.

In some embodiments, introducing additional encapsulating liquid occurs when a water-sensitive dye in the encapsulating liquid changes color.

In some embodiments, a method of replenishing an encapsulating liquid includes removing a portion of the encapsulating liquid from the overlayer.

In some embodiments, a method of replenishing an encapsulating liquid includes removing water from the portion of the encapsulating liquid; reintroducing the portion of the encapsulating liquid to the liquid-based encapsulation system.

In some embodiments, a method of replenishing an encapsulating liquid includes introducing a second encapsulating liquid to the liquid-based encapsulation system.

In one aspect, a method of making a liquid-based encapsulation system includes providing an electronic material having a plurality of exposed surfaces; and encapsulating the electronic material with an encapsulating liquid over an entirety of the exposed surfaces of the electronic material to prevent diffusion of water past the encapsulating liquid and to protect the electronic material from water.

In some embodiments, encapsulating the electronic material with the encapsulating liquid includes coating the electronic material with a coating material that conformally surrounds the electronic material; and infusing the coating material with the encapsulating liquid.

In some embodiments, the coating material is a polymer.

In some embodiments, the coating material is a porous material.

In some embodiments, a method of making a liquid-based encapsulation system includes disposing the encapsulating liquid and the electronic material in a container.

### BRIEF DESCRIPTION OF THE DRAWINGS

FIG. 1 shows an water-sensitive material encapsulated in an encapsulating liquid, in accordance with certain embodiments.

FIG. 2 shows tunable properties of an encapsulating liquid, including surface slipperiness, optical properties, mechanical properties, and self-cleaning, in accordance with certain embodiments.

FIG. 3 shows the transmittance of an encapsulating liquid and glass at UV and visible wavelengths, in accordance with certain embodiments.

FIG. 4A shows a solid state encapsulation of an water-sensitive material.

FIG. 4B shows an water-sensitive material with an encapsulating liquid-infused polymer and an encapsulating liquid overlayer, in accordance with certain embodiments.

FIG. 5 shows a typical conductance curve of a solid-state encapsulation, corresponding to the remaining thickness of a metal subject to corrosion when exposed to moisture as a function of time.

FIG. 6A shows an encapsulating liquid overlayer formed over an encapsulating liquid-infused polymer, in accordance with certain embodiments.

FIG. 6B shows confinement of an encapsulating liquid by a polymer matrix, in accordance with certain embodiments.

FIG. 6C shows replenishment of an encapsulating liquid overlayer, in accordance with certain embodiments.

FIG. 7A shows an encapsulating liquid-infused polymer under tensile stress, in accordance with certain embodiments.

FIG. 7B shows an encapsulating liquid-infused polymer under compressive stress, in accordance with certain embodiments.

FIG. 7C shows an encapsulating liquid-infused polymer under bending stress, in accordance with certain embodiments.

FIG. 8A shows a porous material infused with an encapsulating liquid, in accordance with certain embodiments.

FIG. 8B shows an inverse opal infused with an encapsulating liquid, in accordance with certain embodiments.

FIG. 9 shows the deterioration of a perovskite film with an encapsulating liquid infused polymer in a water bath without replenishment (top) and with daily replenishment (bottom), in accordance with certain embodiments.

FIG. 10 shows a model of water concentration as a function of distance across the encapsulating liquid overlayer and encapsulating liquid-infused polymer layer at different time points before and after replenishment, in accordance with certain embodiments.

FIG. 11 shows a model of water concentration as a function of distance across the encapsulating liquid overlayer and encapsulating liquid-infused polymer layer at different time points after replenishment, in accordance with certain embodiments.

FIG. 12 shows the theoretical quantity of water in an encapsulating liquid-infused polymer before and after replenishment, in accordance with certain embodiments.

FIG. 13 shows the concentration profile over time for one replenishment occurring at t=1000 (arbitrary units), in accordance with certain embodiments.

FIG. 14 shows the concentration profile over time for three replenishments occurring at t=1000, t=2000, and t=3000 (arbitrary units), in accordance with certain embodiments.

FIG. 15A shows an encapsulation system with a water-sensitive dye and water concentration below a critical level, in accordance with certain embodiments.

FIG. 15B shows an encapsulation system with a water-sensitive dye and water concentration after it reaches a critical level, resulting in a color change indicating a need to replenish the encapsulating liquid, in accordance with certain embodiments.

FIG. 16 shows an encapsulation system for replenishment of the encapsulating liquid, including an inlet, an outlet, a water removal unit, and a pump, in accordance with certain embodiments.

FIG. 17 shows a multilayered encapsulation system in a rigid container, in accordance with certain embodiments.

FIG. 18 shows a multilayered encapsulation system in a flexible container composed of an infused polymer, in accordance with certain embodiments.

FIG. 19A shows an encapsulation system in a rigid container with a microorganism capable of converting H₂O and CO₂ to carbon oil through photosynthesis, in accordance with certain embodiments.

FIG. 19B shows an encapsulation system in a flexible container composed of an infused polymer with a microorganism capable of converting H₂O and CO₂ to carbon oil through photosynthesis, in accordance with certain embodiments.

FIG. 20A shows an encapsulation system in a rigid container with a microorganism capable of converting H₂/H₂O and N₂ into NH₃ through a nitrogen fixation process, in accordance with certain embodiments.

FIG. 20B shows an encapsulation system in a flexible container composed of an infused polymer with a microorganism capable of converting H₂/H₂O and N₂ into NH₃ through a nitrogen fixation process, in accordance with certain embodiments.

FIG. 21A shows an encapsulation system in a rigid container with an inorganic semiconductor capable of splitting H₂O into H₂ and O₂ through artificial photosynthesis, in accordance with certain embodiments.

FIG. 21B shows an encapsulation system in a flexible container composed of an infused polymer with an inorganic semiconductor capable of splitting H₂O into H₂ and O₂ through artificial photosynthesis, in accordance with certain embodiments.

FIG. 22A shows a multilayered system containing microorganisms and inorganic semiconductors in a rigid container, in accordance with certain embodiments.

FIG. 22B shows a multilayered system containing microorganisms and inorganic semiconductors in a flexible container composed of an infused polymer, in accordance with certain embodiments.

FIG. 23A shows a multilayered system containing microorganisms and inorganic semiconductors in a rigid container, including a layer adjacent to the encapsulated material that contains pure encapsulating liquid, in accordance with certain embodiments.

FIG. 23B shows a multilayered system containing microorganisms and inorganic semiconductors in a flexible container composed of an infused polymer, including a layer adjacent to the encapsulated material that contains pure encapsulating liquid, in accordance with certain embodiments.

FIG. 24 shows the stability of perovskite with a polymer coating infused with encapsulating liquids of different viscosities, in accordance with certain embodiments.

FIG. 25 shows the deterioration of a perovskite film with a coating infused with a lower viscosity encapsulating liquid (top) compared to a perovskite film with a coating infused with a higher viscosity encapsulating liquid (bottom), in accordance with certain embodiments.

FIG. 26A shows the uptake of encapsulating liquids of different viscosities by a polymer, in accordance with certain embodiments.

FIG. 26B shows the stability of perovskites in water when encapsulated by a polymer infused with encapsulating liquids of different viscosities, in accordance with certain embodiments.

FIG. 27A shows perovskite coated with a Teflon film infused with an encapsulating liquid, in accordance with certain embodiments.

FIG. 27B shows pinning of water droplets on uncoated perovskite, Teflon®-coated perovskite, and liquid-infused Teflon®-coated perovskite, in accordance with certain embodiments.

FIG. 28A shows the deterioration of perovskite coated with a Teflon® film, according to certain embodiments.

FIG. 28B shows perovskite coated with a liquid-infused Teflon film, according to certain embodiments.

FIG. 29A shows a dry crosslinked fluorinated polymer matrix (fluorogel)-coated halide perovskite thin film immersed in water, according to certain embodiments.

FIG. 29B shows a low-viscosity oil-infused, crosslinked fluorinated polymer matrix (fluorogel)-coated halide perovskite thin film immersed in water, according to certain embodiments.

FIG. 29C shows a high-viscosity oil-infused, crosslinked fluorinated polymer matrix (fluorogel)-coated halide perovskite thin film immersed in water, according to certain embodiments.

FIG. 30A shows a cross-sectional 2D confocal microscope optical image of dye distribution in a dry fluorogel, according to certain embodiments.

FIG. 30B Cross-sectional 2D confocal microscope dark-field fluorescent image of dye distributions in a dry fluorogel, according to certain embodiments

FIG. 30C Fluorescence intensity profile as a function of film depth, according to certain embodiments.

### DETAILED DESCRIPTION

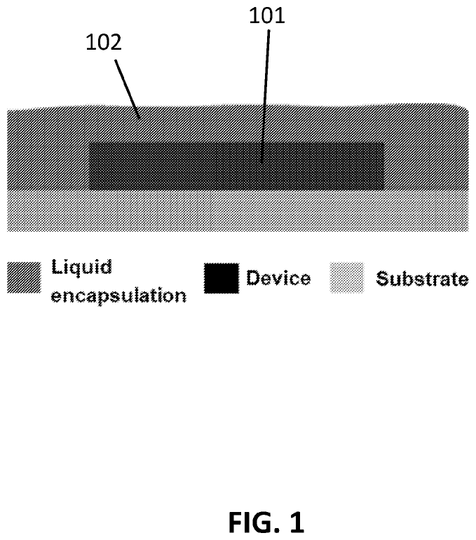

In one embodiment, shown in FIG. 1, a liquid encapsulation system includes a water-sensitive material 101 or device encapsulated in an encapsulating liquid 102 over part or over the entirety of the exposed surfaces of the water-sensitive material to prevent diffusion of water past the encapsulating liquid and to protect the water-sensitive material from water or other environmental contaminants or conditions. In some embodiments, a polymer surrounds the water-sensitive material, and the polymer is infused with the encapsulating liquid. In some embodiments, the water-sensitive material is a material for or within an electronic or microelectronic device. In some embodiments, a porous material surrounds the water-sensitive material, and the porous material is infused with the encapsulating liquid. In some embodiments, the water-sensitive material 101 and encapsulating liquid 102 are contained within a container. In some embodiments, the container is rigid or flexible or a combination of the two. In some embodiments, the container is combined with a polymer or porous material that surrounds the water-sensitive material and is infused with the encapsulating liquid.

In some embodiments, encapsulating liquids meet many of the demands of encapsulation as they are free of defects down to the molecular scale, repellent to water droplets and ice, easily renewable, and self-healing, and have tunable mechanical and optical properties. In some embodiments, the encapsulating liquid is hydrophobic. In some embodiments, the encapsulating liquid forms a dynamic barrier that lubricates the surface of the encapsulated water-sensitive material, self-heals upon perturbation, self-cleans the surface, and is replenished; in some embodiments, these macroscopic functions of the encapsulating liquid can be co-optimized In some embodiments, the molecules of the encapsulating liquid on the surface deters water absorption. In some embodiments, the molecules of the encapsulating liquid constantly move around, leading to narrower time window to bond with water molecules compared with stationary polymer molecules. In some embodiments, the molecules of the encapsulating liquid in bulk and locally confined by polymer chains seal defective volumes and increase the free energy barrier of water vapor diffusion. In some embodiments, periodic replenishment of the encapsulating liquid purges away any water molecules dissolved in the surface overlayer. In some embodiments, the water molecules in the encapsulating liquid, if any, diffuse upward to the surface driven by the concentration gradient resulting in impeding the downward from the surface diffusion of water.

### I. ENCAPSULATED MATERIALS AND DEVICES

In some embodiments, encapsulating liquids are used to encapsulate materials that are sensitive to water and other environmental factors. In some embodiments, the materials are sensitive to water, water vapor, or moisture. In some embodiments, the encapsulated materials are electronic materials, electronic devices, or electronic components. In some embodiments the encapsulated materials are perovskite devices, for example, perovskite photovoltaic cells.

Solid encapsulation materials include ceramics, plastics and elastomers. Ceramics (e.g., glass, aluminum oxides, aluminium nitrides) possess exceptional electrical, thermal, mechanical, and dimensional stability properties. On the other hand, ceramics are brittle and sensitive to stress corrosion, making them prone to catastrophic failure. The high fabrication cost, typically 10 times higher than that of plastic packages, further limits the growth of ceramics in the encapsulation market. Plastics made from thermoset polyether have been the dominating encapsulation material for microelectronics. After a half of century, endeavors in improving both fabrication process and material chemistry, plastic encapsulations outperform ceramics in the areas of size, weight, performance, cost, reliability, and availability.

Halide perovskite solar cells, organic light emitting diodes, flexible electronics, batteries, supercapacitors, wearable sensors and energy harvesters, implantable biomedical devices, and soft robotics have raised a number of unprecedented challenges for encapsulation designs that cannot be solved by plastic encapsulations. The encapsulation of these devices should not only seal out water and oxygen in all forms (e.g., vapor, drop, ice, biofluid), but simultaneously be optimized for mechanical flexibility, durability, temperature resistance, pressure stability, optical selectivity, self-cleaning, self-repair, scalability, and low cost. No solid-state encapsulation is available that can meet these demands.

### A. Electronic Circuits

In some embodiments, the encapsulated material is an electronic circuit, for example, an integrated circuit. The function of an electronic circuit depends on governing electron transfer between different electrodes. For example, when the circuit is exposed to liquid water, ions in water will induce unwanted electron conductance, leading to short circuiting. Alternatively, water vapor damages a circuit by gradually oxidizing the metal electrodes and converting the metal electrodes from conductors to insulators. In some embodiments, in addition to water, other polar molecules, such as alcohols, acids, bases, in liquid, vapor or solid form, alone or in mixtures are other environmental factors that are be damaging to electronic circuits. In some embodiments, the heat produced during the operation of an integrated circuit damages the electron conducting channel of the circuit.

In some embodiments, the encapsulated material is a flexible electronic. Flexible electronics similarly require effective encapsulation to prevent the diffusion of water and other polar molecules. Similar to rigid electronic devices, flexible electronics are damaged by decomposition of semiconductor, oxidation of electrodes, or short circuiting. However, when encapsulating flexible electronics, the encapsulation material must be mechanically flexible to accommodate the mechanical deformation without creating defects in the encapsulating layer. This requirement limits the material selection to soft matter. In some embodiments, the encapsulation should be tough to protect flexible devices from physical damage such as scratches and fracture. In some embodiments, long-time exposure to UV light and heat decomposes the organic components in the flexible electronic. In some embodiments, in addition to water, other polar molecules, such as alcohols, acids, bases, in liquid, vapor or solid form, alone or in mixtures are other environmental factors that are damaging to flexible electronics.

### B. Perovskite Photovoltaic Cells

In some embodiments, the encapsulated material is a halide perovskite. Halide perovskite is an ionic semiconductor with the formula ABX₃, where cation A is usually either methylammonium, formamidinium, cesium, or a mixture of them, cation B could be lead, tin, or their mixture, and anion X is chlorine, bromine, iodine or their mixtures. This perovskite family encompasses an unprecedented combination of optoelectronic properties including tunable direct bandgap (1-3 eV) with strong optical absorption and emission over the visible spectrum; low binding energy of excitons (˜0.03 eV); high carrier mobility (˜7.5 and ˜12.5 cm² V⁻¹ S⁻¹ for electrons and holes, respectively); long charge diffusion length (100-1000 nm), and high tolerance to defects. These features enable halide perovskite to surpass all existing semiconductors for low-cost, solution-processable polycrystalline thin film solar cells with high power conversion efficiency.

The application of halide perovskite materials is limited by the poor chemical stability of halide compounds. The halide perovskite is sensitive to all forms of polar molecules, including water. The high polarity of water molecules drastically reduces the binding energy between ions in perovskites and breaks the bonds, causing the perovskites to dissolve in water as quickly as salts. Therefore, the desired properties of halide perovskites are limited by water sensitivity. In some embodiments, in addition to water, other polar molecules, such as alcohols, acids, bases, in liquid, vapor or solid form, alone or in mixtures are other environmental factors that are damaging to perovskite materials.

Other external stimuli, including ultraviolet light (UV), electric field, heat, and mechanical stress, also disassociate the perovskite, especially in a humid environment. The UV light and electric field can migrate halogens and create halogen vacancy-interstitial pairs. The prototypical perovskite, methylammonium lead iodide (CH₃NH₃PbI₃), decomposes at a temperature above 130° C., which is the typical temperature used to package solar panels using solid-state encapsulations. Perovskites have low fracture energy (below 1 J/m²) and high thermal expansion coefficient (10 times higher than that of glass substrate). The nontrivial mechanical stress built up during temperature change can cause delamination or accelerated decomposition. The detrimental influence of UV, electric field, and mechanical stress will be exacerbated by the presence of water. Water molecules can form strong hydrogen bonds with the organic cations of perovskites and resultantly weaken the binding between the cation and complex anion moieties, leading to the promoted deprotonation of the organic cation in response to external stressors. These factors collectively make the perovskite optoelectronics degrade fast in ambient environment. The operational stability is the biggest obstacle constraining the access to the low-cost, renewable electricity from PSCs.

For example, to protect halide perovskite solar cells (PSCs), a wide range of solid encapsulations composed of glass, oxide, and polymer have been individually or jointly introduced. The combination of glass sheets and polymer seal aligns with industrial interests in terms of cost, but suffers from gradual vapor ingress from the edge seal. Oxide thin film coatings are flexible and light-weight; their resistance to gas permeation is however limited by defect-induced vapor penetration. There exists a “critical film thickness” in these thin film coatings, typically tens of nanometers, above which the gas permeation rate does not decrease further with the increase of film thickness. The inorganic/polymer multilayer laminate used in organic light emitting diodes is an effective encapsulation, but its fabrication requires sophisticated vacuum deposition equipment. The fabrication cost increases abruptly and sharply with the increase of sample size, meaning these laminates will not be a viable option for industrial solar panels. A simplified derivative technology—oxide coated polymer—does not provide comparable performance. The hydrophobic polymer (e.g., crosslinked fluorinated polymer) sets the record of perovskite outdoor stability to about 90 days (stable in liquid water for 1 day), but the free space between polymer chains allows diffusion of water and impedes the further improvement of the protection. The current lifetime benchmark of perovskite solar cell is far behind the commercial requirement suggested by International Electrotechnical Commission (>10 years). Furthermore, solid encapsulations are prone to defects, which allow water vapor permeation.

### II. LIQUID ENCAPSULATION OF WATER-SENSITIVE MATERIALS AND DEVICES

In some embodiments, at the surface of an encapsulation system, an encapsulating liquid encapsulates a water-sensitive material, repels water (including ice), and prevents diffusion of water while providing multiple functionalities including optical transparency, pressure stability, self-cleaning, and self-healing. In some embodiments, the encapsulating liquid also keeps the surface defect-free down to the molecular scale by self-eliminating, artifact/damage-induced low-energy diffusion pathways. In some embodiments, the fluidic nature of the encapsulating liquid further allows the system to be periodically purged of dissolved water molecules by replenishment of the encapsulating liquid. In this embodiment, the encapsulating liquid both within and on top of the material is kept “fresh,” preventing transition to steady vapor flow. These properties will collectively give rise to an ultralow water vapor transport rate (WVTR) and a comprehensive integration of various functions.

### A. Encapsulating Liquids

In some embodiments, an encapsulating liquid surrounds the entirety of water-sensitive material to protect the water-sensitive material from the environment. In some embodiments, a liquid alone protects the water-sensitive material from the environment. In some embodiments, the water-sensitive material is provided with a coating material that conformally surrounds the water-sensitive material, and the encapsulating liquid infuses into the coating material and forms an overlayer over the coating material. In some embodiments, the encapsulating liquid is hydrophobic and repels water. In some embodiments, an encapsulating liquid includes molecules possessing hydrocarbon, fully or partially fluorinated moieties of various chain length and structure, the said moieties having functional groups (e.g., ether, ester) or other heteroatoms (e.g., oxygen or nitrogen) within them, and combinations thereof provide a tunable range of hydrophobicity.

### 1. Properties of Encapsulating Liquids

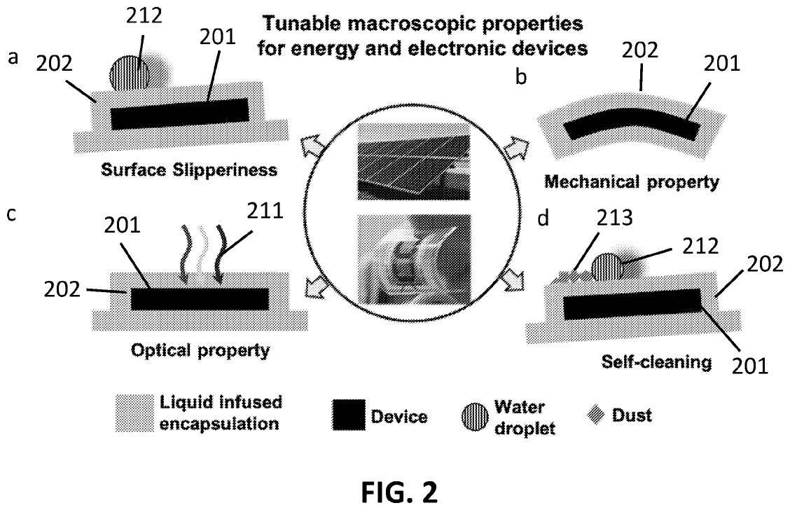

In some embodiments, shown in FIG. 2 (views a-d) the encapsulating liquid 202 has additional tunable properties that are desirable for water-sensitive materials 201. Non-limiting examples of tunable properties include surface slipperiness, mechanical properties, optical properties, self-healing, and self-cleaning. In some embodiments, these properties are combined for an encapsulating liquid with any combination of these properties. In some embodiments, these properties can be co-optimized. In some embodiments, these properties of the encapsulating liquid are tuned by e.g., varying chemical nature of the liquid, the molecular weight and structure of comprising molecules, through utilizing mixtures of liquids. In some embodiments, mixtures include encapsulating liquids from the same, similar or different chemical class.

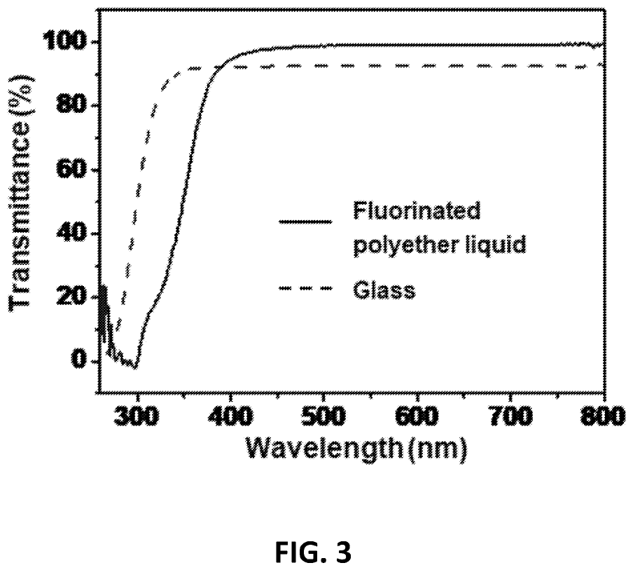

In some embodiments, the encapsulating liquid has high optical transparency. For example, high optical transparency is desirable for the encapsulation of optoelectronic devices. In some embodiments, shown in FIG. 2 (view c), the encapsulating liquid 202 are selected to be transparent to light 211 of a particular wavelength. In some embodiments, shown in FIG. 3 the encapsulating liquid is more transparent than glass. FIG. 3 shows the optical transparency (i.e., transmittance) of a fluorinated polyether liquid (Krytox lubricant) in the UV (250-400 nm) and Visible (400-800 nm) wavelength ranges, compared to the optical transparency of glass in the same wavelength ranges. The visible light transparency of the fluorinated polyether liquid is 99%, while the optical transparency of the glass is only about 92%. The 7% improvement enabled by liquid encapsulation leads to higher efficiency of optoelectronic devices.

In some embodiments, viscosity of the liquid are used to tune the vapor transport rate of the encapsulating liquid. According to the Einstein-Stokes relationship, the diffusion coefficient of water molecules in a hydrophobic liquid is inversely proportional to the viscosity of the hydrophobic liquid. Therefore, in some embodiments, a viscous liquid is more effective in preventing diffusion of water molecules.

In some embodiments, an encapsulating liquid has a self-healing capability because liquid flows into and seal any damaged areas. In some embodiments, this flow is driven by chemical potential. As used herein, “self-healing” refers to re-formation of an ultra-smooth (and even substantially molecularly flat) surface after physical impact (e.g., damage). For example, the surface self-heals on a time scale that is faster than 100 s, 10 s, 1 s, or even 100 ms. In some embodiments, the self-healing behavior of a liquid-based encapsulation system is a function of the interaction between the encapsulating liquid and a surface, thickness of the liquid film, as well as the viscosity of the encapsulating liquid. Typical kinematic viscosities of an encapsulating liquid are in the range of 0.10 cm²/s to 10 cm²/s. In some embodiments, particle impact or scratching damages the surface by, for example, breaking or removing the topological features of the surface in a small area. In some embodiments, the impact also displaces the encapsulating liquid, resulting in a scratch or pit and exposing the water-sensitive material. Due to the wicking capability and good wetting properties of the encapsulating liquid, however, the encapsulating layer flows back to refill a pit or scratch and to regenerate the smooth fluid surface. In some embodiments, this self-healing behavior relies on the availability of sufficient amounts of the encapsulating liquid in the areas adjacent to the damaged area within the encapsulating liquid overlayer. In some embodiments, the overlayer serves as a reservoir of the encapsulating liquid. In some embodiments, tailoring parameters of the liquid-infused polymer such as polymer bond energy, cross-linking density, and the encapsulating liquid's chemical and physical properties (e.g., polarity and viscosity) allows fine control over the flow dynamics of the liquid and thus the self-healing dynamics of the encapsulation.

In some embodiments, the encapsulating liquid provides a slippery surface. In embodiments where devices operate under outdoor conditions (e.g., solar cells), surface slipperiness is desirable for encapsulation to protect the device from water droplets or other debris. In some embodiments, shown in FIG. 2 (view a), introducing an encapsulating liquid eliminates the pinning of water droplets 212 on the surface of a water-sensitive material.

In some embodiments, shown in FIG. 2 (view b), encapsulating liquids endure mechanical deformations. In some embodiments, when used in flexible devices, encapsulating layers are frequently exposed to mechanical deformations. Liquid encapsulations endure higher strain compared with solid encapsulation. In some embodiments, the self-healing capacity of the encapsulating liquid contributes to the ability to endure mechanical deformation.

In some embodiments, shown in FIG. 2 (view d) the encapsulating liquid is self-cleaning and dust 213 and water droplets 212 cannot adhere to the surface of the encapsulating liquid.

2. Protecting Water-Sensitive Materials from the Environment with Encapsulating Liquids
a. Prevention of Water Diffusion

In some embodiments, diffusion of water, such as diffusion of water vapors, is minimized by increasing the free energy barrier of diffusion of water across the encapsulating liquid.

The diffusion of water molecules is driven by Brownian motion, and the diffusion coefficient D is related to the temperature T by the Arrhenius relation:

$$D ( T ) = {D}_{0} {e}^{- \frac{{E}_{A}}{{k}_{B} T}}$$

where D₀ is the pre-exponential factor (m²·s⁻¹), k_{B} is the Boltzmann constant, T is the temperature, and E_{A} is the activation energy. The Arrhenius equation shows that the higher the energy barrier, the lower the diffusion coefficient at a given temperature.

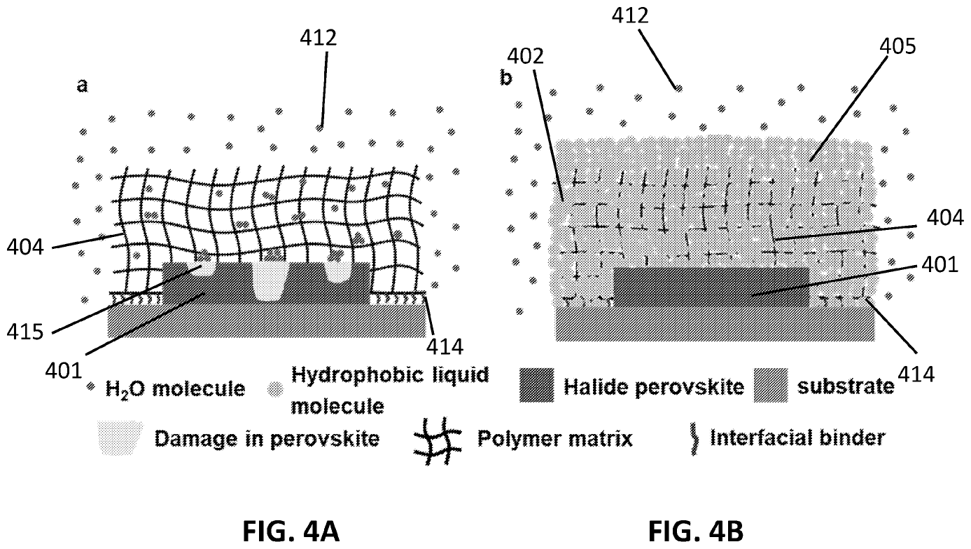

In one embodiment, a liquid-infused polymer is used to elucidate the mechanism of preventing water diffusion at the molecular level. FIGS. 4A-4B show differences between a solid-state encapsulation and a liquid encapsulation. FIG. 4A shows a solid-state encapsulation formed by a dry polymer matrix 404 alone. In one embodiment, FIG. 4B shows a liquid-infused encapsulation formed by a polymer matrix 404 infused with an encapsulating liquid 402. In the embodiments shown in FIGS. 4A-4B, halide perovskite is the exemplary protected water-sensitive material 401. In this embodiment, shown in FIG. 4B, the encapsulating liquid 402 infuses the polymer matrix 404 and forms an overlayer 405 over the polymer matrix 404.

First, as shown in FIG. 4A, solid-state encapsulations unavoidably contain low-energy barrier pathways that allow water 412 to penetrate with relative ease. Non-limiting examples of these pathways include edges in laminated packaging, voids in porous coating, bulk defects in crystals, interfacial binders 414, and empty spaces between polymer chains in cross-linked polymer matrix. Water 412 penetrates via these pathways to reach the electronic device 401 to create damage 415. In contrast, in some embodiments, shown in FIG. 4B an encapsulating liquid 402 flows into these empty channels driven by chemical potential, tightly sealing the low-energy channels. In some embodiments, the surface overlayer in the liquid-infused design shown in FIG. 4B includes liquid molecules (e.g., oil molecules) that have long-range mobility and constantly exchange positions with neighboring molecules. As a consequence, the time window for water molecules to build an effective bonding with the surface is substantially shortened compared with a solid interface shown in FIG. 4A.

Second, as shown in FIG. 4B, a hydrophobic liquid overlayer 405 promotes the clustering effects of water molecules. Water diffusion in cluster form experiences a larger free energy barrier when diffusing through a hydrophobic liquid than in the single water molecule form due to increased chemical and physical hindering. In addition, water clusters will exert a mean-field attractive force on the surrounding water molecules, diverting them from diffusing into the matrix. In some embodiments, the presence and the type of the polar moieties within encapsulating liquid molecules affects the formation of water clusters. For example, presence or absence and frequency of appearance of ether-, ester- or amino-linkages within the molecules of encapsulating liquid impart different degrees of water clustering.

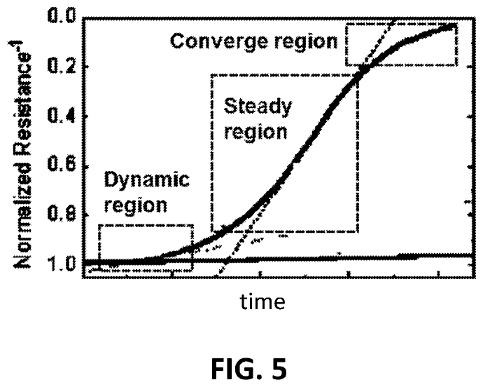

Lastly, the fluidic nature of an encapsulating liquid barrier allows the encapsulation to operate under a dynamic fashion. The penetration of water molecules into an encapsulation typically undergoes two stages as shown in the conductance curve obtained from the measurement of water vapor transport rate shown in FIG. 5: (1) the dynamic region in which a water concentration gradient builds up across the encapsulating liquid; (2) the steady-state transport of water molecules through the encapsulating liquid. The water vapor transport rate (WVTR) of the dynamic stage is several orders of magnitude lower than that of the steady stage. The solid-state encapsulations enter steady-state transport eventually, meaning solid state encapsulations are designed to limit the steady-state WVTR below the target bar. In some embodiments, this unfavorable scenario is circumvented with an encapsulating liquid through periodic replenishment or refreshment of the encapsulating liquid overlayer. In some embodiments, replenishing the encapsulating liquid not only allows direct removal of water trapped in the overlayer 405 but also induces any water molecules that may be present in the encapsulating liquid infused polymer layer to diffuse out of the encapsulating liquid infused polymer layer, driven by the concentration gradient. In some embodiments, these transport phenomena are influenced by the judicious choice of the encapsulation liquids used initially and at the replenishment stage.

b. Reduction of Water Adsorption

In addition, a liquid overlayer can substantially reduce water adsorption. While symmetry attributes are broken at the surface of a solid layer, leading to a local polarity that favors water adsorption, this unfavorable mechanism may be thwarted by the liquid overlayer in a liquid-infused design. Indeed, liquid molecules on the surface have a much higher mobility when compared to solid polymer molecules, and the liquid molecules constantly exchange positions with neighboring molecules. As a result, the time window for incoming water molecules to build an effective interaction with the liquid surface is shortened compared to the time window for building an effective interaction with a solid surface.

c. Protection from UV Light

In some embodiments, the encapsulating liquid provides protection from ultraviolet (UV) light. In some embodiments, for example optoelectronics or photovoltaics, it is desirable to have a high transmittance of visible light for the function of the water-sensitive material. However, in some embodiments, the encapsulated water-sensitive material degrades when exposed to UV wavelengths, and it is desirable to block UV light. In some embodiments, the encapsulating liquid is selected to have a high transmittance at wavelengths that are useful for the function of the water-sensitive material but low transmittance at wavelengths that contribute to degradation of the water-sensitive material. As shown in FIG. 3, liquid encapsulation blocks a larger portion of UV light (<400 nm) compared with glass, as evidenced by the lower transmittance of a fluorinated polyether liquid below 400 nm compared to the transmittance of glass at the same wavelengths. In some embodiments, the encapsulating liquid further reduces the UV transparency by incorporating UV reflectors or absorbers into the liquid medium. Non-limiting examples of UV reflectors or absorbers include zinc oxide, titanium oxide particles, carbon black, avobenzone, oxybenzone, octyl methoxycinnamate, and combinations thereof.

d. Protection from Changes in Temperature

In some embodiments, encapsulating liquids provide protection from changes in temperature. Compared with solid encapsulation, the encapsulating liquid protects devices from temperature variations because the specific heat capacity of a hydrophobic encapsulating liquid is higher than the specific heat capacity of a solid encapsulation. For example, the specific heat capacity of vegetable oil is 2 J/g° C., which is more than twice the specific heat capacity of glass (0.84 J/g° C.). In some embodiments, high heat capacity is preferred for an encapsulation as high heat capacity minimizes the temperature variation in the surroundings of the device. In some embodiments, the heat capacity of the liquid is tuned by controlling the elemental composition and spatial structure of the liquid molecules. In some embodiments, the effective heat capacity of the encapsulation is tuned by manipulating the mass ratio between the liquid and the solid scaffold.

### 3. Examples of Encapsulating Liquids

In some embodiments, the encapsulating liquid is a hydrophobic liquid. In some embodiments, the encapsulating liquid is hydrophobic for encapsulation of devices that highly sensitive to water. In some embodiments, encapsulating liquid molecules include polar moieties. Non-limiting examples of polar moieties include ether-, ester- or amino-linkages within the molecules of encapsulating liquid.

In some embodiments, encapsulating liquid includes a liquid in the top layer that is hydrophilic. In some embodiments, the encapsulating liquid is hydrophilic for the encapsulation of devices that have water as a reactant or product. Non-limiting examples of devices that have water as a reactant or product include fuel cells and photoelectrochemical cells for water splitting. In some embodiments, the hydrophilic encapsulating liquid protects these devices from corrosive ions.

In some embodiments, the encapsulating liquid is a lubricant. In some embodiments, a lubricant is used for encapsulation of devices that require high surface slipperiness for repelling droplet and ice. In some embodiments, the encapsulating liquid is a chemically-inert, high-density liquid. In some embodiments, a chemically-inert, high-density encapsulating liquid encapsulates devices that are sensitive to the water vapor or oxygen gas. In some embodiments, the encapsulating liquid is a chemically-inert, high-density liquid.

In some embodiments, the encapsulating liquid is a perfluorinated liquid or partially fluorinated liquid. In some embodiments, partial fluorination leads to a stepwise reduction in specific gravity, while hydrogenation leads to augmented polarization and increased lipophilic or silicone-solvent properties. In some embodiments, the encapsulating liquid includes multiple classes of partially fluorinated inert liquids, including oligomers and mixtures. The physical and chemical properties make partially fluorinated inert liquids suitable for this application, as well. A number of types and classes of such liquids are listed throughout this application and in the examples. A person skilled in the art will recognize that the list and the examples are non-limiting and there are multiple variations and permutations, not listed here, of infused polymer/infusing partially fluorinated liquid that will work similarly well for the purposes of protecting a water-sensitive electronic materials and devices. Non-limiting examples of perfluorinated liquids or partially fluorinated liquids include fluorocarbons, perfluorocarbons, hydrofluorocarbons, hydrofluorocarbon-oligomers, compounds having partially fluorinated ponytails, partially fluorinated oils, partially fluorinated greases, fluorosilicones, tertiary perfluoroalkylamines (such as perfluorotri-n-pentylamine, FC-70, perfluorotri-n-butylamine FC-40, etc.), perfluoroalkylsulfides and perfluoroalkylsulfoxides, perfluoroalkylethers, perfluorocycloethers (like FC-77) and perfluoropolyethers (such as KRYTOX family of lubricants by DuPont), perfluoroalkylphosphines and perfluoroalkylphosphineoxides, perfluorohexyl-octane, perfluorohexyl-ethane, perfluorobutyl-butane, perflurophenanthren, perfluorooctane, perfluorophenathrene, and their analogues, homologues, oligomers, polymers, mixtures, and combinations thereof. In some embodiments, perfluoroalkyls are linear or branched. In some embodiments, the encapsulating liquid includes a hydrofluorocarbon oligomer. In some embodiments, hydrofluorocarbon oligomers include two to four hydrofluorocarbon molecules and have viscosity between 90 and 1750 mPas. In some embodiments, hydrofluorocarbon oligomers include a star-shaped molecular structure with polar, hydrogenated molecules at the center. In some embodiments, long-chain perfluorinated carboxylic acids (e.g., perfluorooctadecanoic acid and other homologues), fluorinated phosphonic and sulfonic acids, fluorinated silanes, and combinations thereof are used as the lubricating liquid. In some embodiments, perfluoroalkyl group in these compounds are linear or branched, and some or all linear and branched groups are only partially fluorinated.

In some embodiments, the encapsulating liquid includes ponytails having the formula (CH₂)ₘR_{fn} where R_{fn} includes at least 6 carbons. In some embodiments, ponytails include branching in the aliphatic segment, e.g., doubly branched or split ponytails ((CH₂)ₗCH[(CH₂)ₘR_{fn}]₂) and triply branched ponytails ((CH₂)ₗC[(CH₂)ₘR_{fn}]₃). In some embodiments, ponytails include branching in the perfluoroalkyl segment. In some embodiments, ponytails include a spacer including atoms between the R_{fn} moiety and the chemically active site. In some embodiments, the spacer is an arene ring, methylene groups or a heteroatom such as oxygen, nitrogen, or silicon. In some embodiments, ponytails include alternating spacer/fluorous/spacer/fluorous segments.

In some embodiments, the encapsulating liquid includes fluorinated oils and liquids. Non-limiting examples of partially fluorinated oils and greases include glutarate, camphorate, tricarballylate, phosphate, phosphonate, ether phospho-nitrilate, and cyanurate derivatives of partly fluorinated alcohols. Non-limiting examples of partly fluorinated alcohols include Bis(ψ′-amyl) 3-methylglutarate, Bis(ψ′-heptyl) 3-methylglutarate, Bis(ψ′-heptyl) 2-methylglutarate, Bis(ψ′-heptyl) d-camphorate, Bis(ψ′-heptyl) 2,2′-dimethyl-methylglutarate, Bis(ψ′-heptyl) 3,3-dimethyl-methylglutarate, Tris(ψ′-amyl) tricarballylate, 1,2,4,5-Tetrakis(ψ′-amyl) pyromellitate, Tris(ψ′-amyl) phosphate, Tris(ψ′-heptyl) tricarballylate, Bis(ψ′-amyl) benzene-phosphate, Bis(ψ′-nonyloxy)-butane, Bis(ψ′-nonyloxy)-hexane, Bis(ψ′-amyl) phosphoninitrilate trimer, (ψ′-amyl) phosphoninitrilate trimer, and Bis(ψ′-amyl) (ψ′-nonyl) cyanurate. In some embodiments, fluorinated liquids include esters or ester-type derivatives with partially fluorinated moieties.

In some embodiments, the encapsulating liquid is a hydrocarbon. Non-limiting examples of hydrocarbons include alkanes, olefins, and their liquid higher homologues, such as oligomers and polymers. In some embodiments the encapsulating liquid is a halogenated hydrocarbon, including halogenated alkanes, halogenated olefins and aromatic compounds.

In some embodiments, the encapsulating liquid is mineral oil, which is composed of light mixtures of higher alkanes from a mineral source. In some embodiments the encapsulating liquid is plant oil or other ester with a long alkyl chain. In some embodiments, the encapsulating liquid is an organosilicone compound (e.g. silicone elastomer or silicone oil).

### B. Liquid Infused Polymers

### 1. Mechanisms of Preventing Water Diffusion

In some embodiments, shown in FIG. 4B, the encapsulation system includes an encapsulating liquid-infused polymer. In this embodiment, the electronic device 401 is provided with a polymer matrix 404 that conformally surrounds the water-sensitive material, and the polymer matrix 404 is infused with an encapsulating liquid 402. In this embodiment, the encapsulating liquid 402 infuses into the polymer matrix and forms an overlayer 405 over the polymer matrix 404. In some embodiments, the polymer is cross-linked. In some embodiments, a container may not be necessary to contain the encapsulating liquid 402 since the encapsulating liquid will be retained over the water-sensitive material 401 by the polymer matrix.

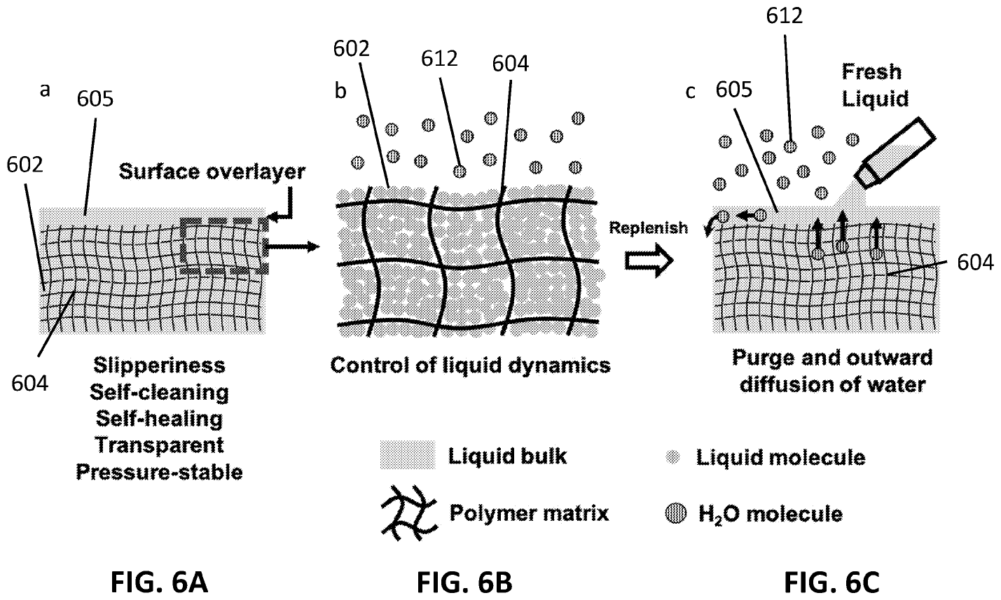

As shown in FIGS. 6A-6C, an encapsulating liquid-infused polymer encapsulation system has several desirable properties. For example, as shown in FIG. 6A, the encapsulating liquid 602 forms an overlayer 605 over the polymer 604, which provides multiple macroscopic functionalities, including slipperiness, self-cleaning, self-healing, transparency, and pressure stability. In some embodiments, shown in FIG. 6B, encapsulating liquid 602 molecules in bulk are locally confined by polymer chains of the polymer matrix 604, increasing the free energy barrier of water vapor 612 diffusion. In some embodiments, shown in FIG. 6C replenishment of the encapsulating liquid 602 periodically purges away any water molecules 612 dissolved in the encapsulating liquid overlayer 605. In some embodiments, during replenishment, the water molecules in the matrix, if any, will diffuse out of the infused polymer 604 and upward to the surface driven by the concentration gradient. In some embodiments, the polymer matrix 604 and confined encapsulating liquid will impede the downward diffusion of water toward the water-sensitive material. Replenishment of the encapsulating liquid is further discussed below.

In some embodiments, shown in FIG. 6B, the molecules of the encapsulated liquid 502 are confined between the polymer chains of the polymer matrix 604. In some embodiments, crosslinking contributes to confinement of the encapsulating liquid. In some embodiments, confining the encapsulating liquid in a polymer matrix further increases the system free energy by reducing the number of configurations and motional degrees of freedom accessible to encapsulating liquid. In this embodiment, the system consequently pays additional energy to reconfigure the spatial distribution of encapsulating liquid molecules to allow water molecules to diffuse. In some embodiments, the infused hydrophobic encapsulating liquid prevents permeation of water vapor 612 within the infused polymer 604 by increasing the free energy barrier of diffusion. In addition to hydrophobicity, the crosslinked polymer matrix controls the liquid dynamics by spatial confinement, which reduces the mobility and number of configurations accessible to encapsulating liquid molecules and further hinders water transport.

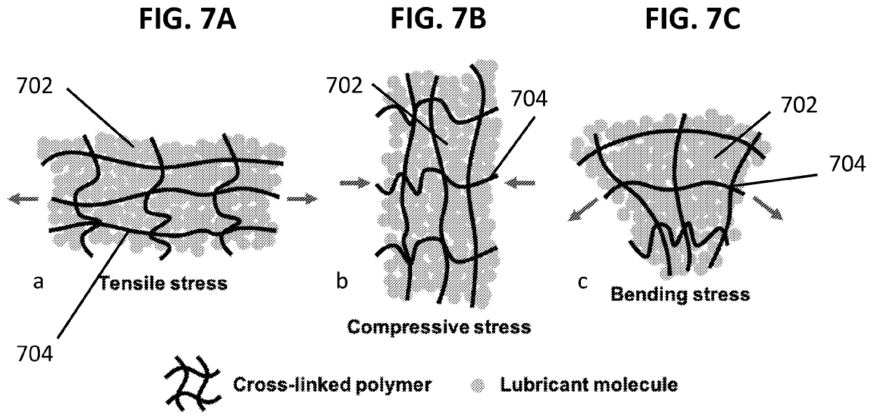

In some embodiments, mechanical deformation alters the geometry of the polymer chains and the dynamics of encapsulating liquid molecules. For example, as shown in FIGS. 7A-7B tensile and compressive stresses reshape the geometry of the polymer matrix 704 through which the confinement of the encapsulating liquid 702 is altered. In areas under tension, the confinement of the liquid is decreased, making it easier for water to diffuse in. In areas under compression, the confinement of liquid is increased, making it harder for water to diffuse in. In some embodiments, tension increases the void space in the polymer matrix, causing additional encapsulating liquid to diffuse into the polymer matrix, diminishing the encapsulating liquid overlayer. As shown in FIG. 7C, bending stress creates asymmetric strains: tensile and compressive at outward and inward surfaces, respectively, giving rise to an inhomogeneous spatial distribution of encapsulating liquid and polymer chains. In areas of tension, it will be easier for water to diffuse in, while in areas of compression, it will be harder for water to diffuse in. In some embodiments, a mechanical deformation is applied to the encapsulation system as a measure to prevent diffusion of water through the encapsulating liquid.

### 2. Tuning of Polymer to Prevent Diffusion of Water

In some embodiments, diffusion of water is prevented by tuning the properties of the polymer matrix, such as cross-linking density, polymer chemistry, polymer chain length, crystallinity, swelling ratio in the encapsulation liquid, and combinations thereof.

In some embodiments, tuning the cross-linking density changes the average pore size of the infused polymer, changing the degree of encapsulating liquid confinement. In some embodiments, increased cross-linking density leads to increased confinement of the encapsulating liquid and decreased diffusion of water into the encapsulating liquid-infused polymer.

In some embodiments, polymer chemistry affects infusion of the encapsulating liquid. In some embodiments, the polymer includes functional groups with an affinity for the encapsulating liquid, which enhances infusion of the encapsulating liquid into the polymer matrix, confinement of the encapsulating liquid within the polymer matrix, and retention of the encapsulating liquid over the polymer matrix. Non-limiting examples of functional groups include perfluoropolyether and alkyl. In some embodiments, the polymer matrix os created at the same time with the encapsulating liquid infusion, resulting in the infused encapsulating liquid trapped within the polymer. In some embodiments, the encapsulating liquid is mixed with the polymer precursors and cured with the polymer precursors to form a polymer matrix. In these embodiments, the affinity between the host polymer and encapsulating liquid is tuned such that the encapsulating liquid is either retained stably within the polymer matrix or is designed to slowly “sweat out” to the surface of the polymer. In some embodiments, the affinity of the polymer and encapsulating liquid is used to tune the desirable diffusion properties of water and other unwanted polar molecules.

In some embodiments, the encapsulating liquid is denser than the polymer matrix, increasing the intake of the encapsulating liquid.

### 3. Examples of Polymers for Infusion

In some embodiments, the polymer is a cross-linked polymer. In some embodiments, the polymer is a gel capable of being swollen with the encapsulating liquid. In some embodiments, the polymer has an affinity for the encapsulating liquid.

In some embodiments, the polymer includes natural and synthetic elastomers such as Ethylene Propylene Diene Monomer (EPDM, a terpolymer of ethylene, propylene and a diene component), natural and synthetic polyisoprenes such as cis-1,4-polyisoprene natural rubber (NR) and trans-1,4-polyisoprene gutta-percha, isoprene rubber, chloroprene rubber (CR), such as polychloroprene, Neoprene, Baypren, Butyl rubber (copolymer of isobutylene and isoprene), Styrene-butadiene Rubber (copolymer of styrene and butadiene, SBR), Nitrile rubber (copolymer of butadiene and acrylonitrile, NBR), also called Buna N rubbers, Epichlorohydrin rubber (ECO), Polyacrylic rubber (ACM, ABR), Fluoroelastomers (FKM, and FEPM) Viton, Tecnoflon, Fluorel, Aflas and Dai-El, Perfluoroelastomers (FFKM) Tecnoflon PFR, Kalrez, Chemraz, Perlast, Polyether block amides (PEBA), Chlorosulfonated polyethylene (CSM), (Hypalon), Ethylene-vinyl acetate (EVA), Polybutadiene, Polyether Urethane, Perfluorocarbon Rubber, Fluoronated Hydrocarbon (Viton), silicone, fluorosilicone, polyurethane, polydimethylsiloxane, vinyl methyl silicone, and their composite materials where one or more of such exemplary polymers are compounded with other filler materials such as carbon black, titanium oxide, silica, alumina, nanoparticles, and the like.

In some embodiments, the polymer is a fluoropolymer. Non-limiting examples of fluoropolymers include polytetrafluoroethylene (Teflon), polyvinylfluoride, polyvinylidene fluoride, fluorocarbon [chlorotrifluoroethylenevinylidene fluoride] (Viton, Fluorel), Fluoroelastomer [Tetrafluoroethylene-Propylene] (AFLAS), perfluorinated elastomer [perfluoroelastomer] (DAI-EL, Kalrez), tetrafluoroethylene (Chemraz), and perfluoropolyether. In some embodiments, the polymer is a fluorosilicone having a PDMS backbone and some degree of fluoro-aliphatic side chains. Non-limiting examples of fluorinated groups in a fluorosilicone include trifluoropropyl, non-afluorohexylmethyl, and fluorinated ethers. In some embodiments, fluorosilicones have variable amounts of fluoro-substitution and lengths of fluorinated side groups. In some embodiments, the polymer includes fluoroalkyl side chains. Non-limiting examples of such polymers include polyfumerate, polymethacrylate, and polyacrylate with fluoroalkyl side chains. In some embodiments such fluoroalkyl side chains have 3, 5, 7, 8, 9, 10, 11, 16, or 18 carbons.

In some embodiments, the polymer includes a polyester, polyethylene terephthalate (PET), polyethylene (PE, HDPE, LDPE), polyvinyl chloride (PVC), polyvinylidene chloride (PVDC), polypropylene (PP), polystyrene (PS, HIPS), polyamides (PA, Nylons), acrylonitrile butadiene styrene (ABS), polyethylene/Acrylonitrile Butadiene Styrene (PE/ABS), polycarbonate (PC), polycarbonate/acrylonitrile butadiene styrene (PC/ABS), polyurethanes (PU), melamine formaldehyde (MF), phenolics (PF) or (phenol formaldehydes, polyetheretherketone (PEEK), polyetherimide (PEI), polylactic acid (PLA), polyalkyl methacrylate (like PMMA), urea-formaldehyde (UF), and combinations thereof.

In some embodiments, a fluorinated polymer is infused with a perfluorinated or fluorinated liquid to form a fluorogel. In some embodiments, a butyl rubber is infused with mineral oil. In other embodiments, a silicone is infused with a silicone oil. In some embodiments, fluorinated and butyl rubber systems protect the device from water and/or polar molecules. In some embodiments, a silicone/silicone oil combination encapsulates devices that use water as a reactant (e.g., fuel cells and photoelectrochemical cells) since silicone system has a relatively high water permeability. Exemplary non-limiting combinations of polymers and encapsulating liquids are shown in Table 1 below. A person skilled in the art will recognize that other combinations comprising the classes of polymers and encapsulating liquids present not necessarily in the same rows in Table 1 can be used, as well. In certain embodiments, encapsulating liquids can contain analogues, homologues, oligomers, polymers, and mixtures of the encapsulating liquids listed in Table 1.

TABLE 1
Exemplary material combination for preparation of slippery swollen polymers.

| | Polymer | Encapsulating Liquid |
|---|---|---|
| Elastomers and | Natural polyisoprene (cis- | Hydrocarbons (Saturated |
| rubbers | 1,4-polyisoprene natural | alkanes and unsaturated |
| | rubber and trans-1,4- | olefin and their liquid |
| | polyisoprene gutta-percha); | oligomers and polymers) |
| | synthetic polyisoprene | halogenated hydrocarbons |
| | Polybutadiene (BR for | liquid (alkane, olefin, and |
| | Butadiene Rubber) | aromatics) |
| | Chloroprene rubber | ester with long alkyl chain |
| | (polychloroprene, Neoprene, | like plant oil |
| | Baypren etc) | |
| | Butyl rubber (copolymer of | |
| | isobutylene and isoprene) | |
| | and halogenated butyl | |
| | rubbers | |
| | Styrene-butadiene rubber | |
| | EPM (ethylene propylene | |
| | rubber, a copolymer of | |
| | ethylene and propylene) and | |
| | EPDM rubber (ethylene | |
| | propylene diene rubber, a | |
| | terpolymer of ethylene, | |
| | propylene and a diene- | |
| | component) | |
| | Epichlorohydrin rubber and | |
| | Polyacrylic rubber | |
| | Silicone rubber | |
| | Polyether block amides | |
| | (PEBA) | |
| | Chlorosulfonated | |
| | polyethylene (CSM), | |
| | (Hypalon) | |
| | Ethylene-vinyl acetate (EVA | |
| | Fluorosilicone Rubber | Perfluorinated or |
| | (FVMQ) | fluorinated lubricants and |
| | Fluoroelastomers (like Viton, | solvents, like (hydro) fluoro |
| | Fluorel, Aflas, Dai-El and | ethers (i.e. Krytox), |
| | other fluoroelastomer | fluorocarbon (i.e. |
| | obtained from fluorinated | Perfluorodecalin), |
| | monomers)_{—} | perfluorocarbons, |
| | Perfluoroelastomers (like | hydrofluorocarbons, |
| | Tecnoflon PFR, Kalrez, | hydrofluorocarbon- |
| | Chemraz, Perlast) | oligomers, compounds |
| | | containing partially |
| | | fluorinated ponytails, and |
| | | other fluorinated liquids |
| | | (FC40, FC70, |
| | | perfluorohexyl-octane, |
| | | perfluorohexyl-ethane, |
| | | perfluorobutyl-butane, |
| | | compounds containing |
| | | partially fluorinated |
| | | “ponytails”, partially |
| | | fluorinated lubricating oils |
| | | and greases, |
| | | fluorosilicones) etc |
| | Silicone elastomers | Silicone oil |
| | (polydimethylsiloxane) | |
| Plastics | Polyester | Hydrocarbons (Saturated |
| | Polyethylene terephthalate | alkanes and unsaturated |
| | (PET) | olefin and their liquid |
| | Polyethylene (PE, HDPE, | oligomers and polymers) |
| | LDPE) | halogenated hydrocarbons |
| | Polyvinyl chloride (PVC) | liquid (alkane, olefin, and |
| | Polyvinylidene chloride | aromatics) |
| | (PVDC) | ester with long alkyl chain |
| | Polypropylene (PP) | like plant oil |
| | Polystyrene (PS, HIPS) | |
| | Polyamides (PA, Nylons) | halogenated hydrocarbons |
| | Acrylonitrile butadiene | liquid (alkane, olefin, and |
| | styrene (ABS) | aromatics) |
| | Polyethylene/Acrylonitrile | ether with high boiling |
| | Butadiene Styrene (PE/ABS) | point like diphenyl ether |
| | Polycarbonate (PC) | ester with long alkyl chain |
| | Polycarbonate/Acrylonitrile | like plant oil |
| | Butadiene Styrene (PC/ABS) | |
| | Polyurethanes (PU) | |
| | Melamine formaldehyde | |
| | (MF) | |
| | Phenolics (PF) or (phenol | |
| | formaldehydes) | |
| | Polyetheretherketone | |
| | (PEEK) | |
| | Polyetherimide (PEI) | |
| | Polylactic acid (PLA) | |
| | Polyalkyl methacrylate (like | |
| | PMMA) | |
| | Urea-formaldehyde | |
| | (UF) | |
| polymer composites | Blend (co)polymer | Hydrocarbons (Saturated |
| | Inorgano-polymer | alkanes and unsaturated |
| | hybrid materials | olefin and their liquid |
| | Nanocomposites with | oligomers and polymers) |
| | carbon tube, | halogenated hydrocarbons |
| | grapheme, particles, | liquid (alkane, olefin, and |
| | clay, inorganic sheets | aromatics) |
| | | ester with long alkyl chain |
| | | like plant oil |
| | | polar organic solvents like |
| | | ketones, esters and |
| | | aldehydes |

### C. Liquid Infused Porous Materials

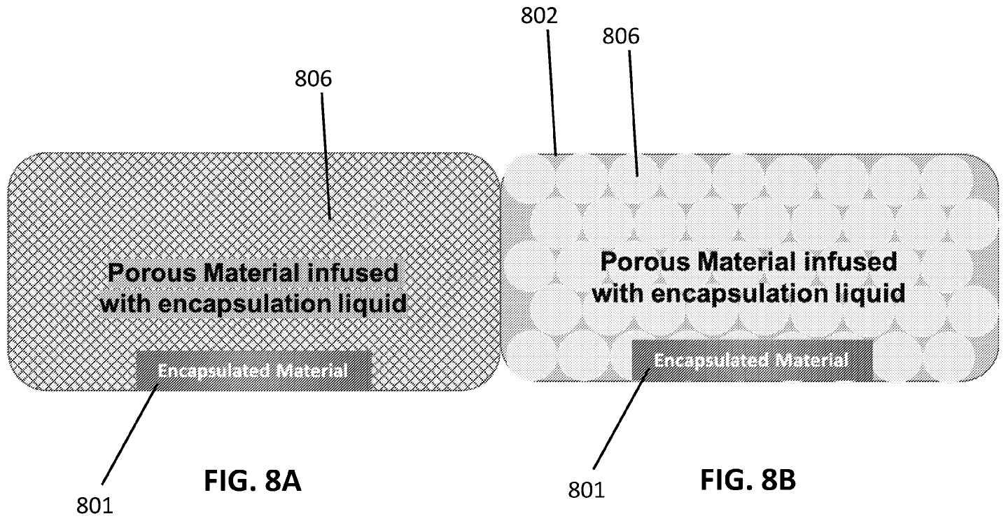

In some embodiments, shown in FIGS. 8A-8B a porous material 806 is infused with large quantities of encapsulating liquid 802. In some embodiments, the porous material is nanoporous, microporous, or milliporous. In some embodiments, a small pore size stabilizes the encapsulating liquid due to the large capillary force and strong local confinement. In some embodiments, a small pore size is advantageous for the applications in outdoor environments, such as rainy and submarine conditions. In some embodiments, large pore size allows more liquid access and a larger portion of the encapsulation that is defect-free. In some embodiments, large pore size is used to encapsulate sensitive devices with low threshold of water exposure in an indoor environment.

In some embodiments, the porous material includes inverse opals, micro- and milli-porous materials that could retain encapsulating liquid over an encapsulated material 801 in large quantities. In some embodiments, the inverse opal scaffold is silica or titania. In some embodiments, the porous materials include pillar arrays, for example, made from Teflon, rubber or alumina. In some embodiments, polymeric porous materials with large pore sizes accommodate the mechanical deformation of flexible devices. In some embodiments, inorganic components are used for fine and precise tuning of pore size for encapsulation of rigid electronic or energy modules.

In one embodiment, FIG. 8A shows the encapsulated material 801 is surrounded by a porous material 806 (flexible or rigid), with pores infused with an encapsulating liquid. In some embodiments, the pores have a size between a few hundred nanometers and several microns. For example, the pores have a size of 100 nm, 200 nm, 300 nm, 400 nm, 500 nm, 600 nm, 700 nm, 800 nm, 900 nm, 1000 nm, 1500 nm, 2500 nm, 3000 nm, 3500 nm, 4000 nm, 4500 nm, 5000 nm, 5500 nm, 6000 nm, 6500 nm, 7000 nm, 7500 nm, 8000 nm, 8500 nm 9000 nm, 9500 nm, 10000 nm, and any value in between

In one embodiment, FIG. 8B shows porous materials 806 that are inverse opals. In some embodiments, an inverse opal has micrometer-size pores. In this embodiment, the inverse opal surrounding the encapsulated material 801 is infused with an encapsulation liquid 802. In some embodiments, these infused porous materials provide additional properties to the encapsulation system. In some embodiments, an inverse opal scaffold allows a fine and precise tuning over the pore size with a precision down to a few nanometers. In some embodiments, an inverse opal accesses a pore size range that is difficult to achieve in polymeric systems. For example, for encapsulations that require precise film thickness and surface slipperiness, the inverse opal scaffold will offer high design accuracy. In some embodiments, the pore size of the inverse opal is precisely tuned by controlling the size of templates used during the inverse opal fabrication.

In some embodiments, the porous material includes a coating on the surface of the pores to provide multiple properties that could complement encapsulation. In some embodiments, the coating increases the affinity of the encapsulating liquid for the porous material. In some embodiments, the coating includes UV absorbers.

### D. Replenishment of Encapsulating Fluid

In some embodiments, over long exposure to ambient humidity or direct contact with liquid water, the local concentration of water in the encapsulating liquid becomes non-negligible when compared to the composition of the initially water-free encapsulating liquid. Solid-state encapsulations necessarily enter steady-state transport of water through the encapsulation eventually. However, unlike a solid state encapsulating material, an encapsulating liquid containing water or saturated with water is replaced with new, fresh encapsulating liquid, improving the lifetime of the encapsulated material. In some embodiments, the timing of replenishment is optimized for particular applications and environments to prevent water molecules from reaching the encapsulated material. In some embodiments, an encapsulating liquid delivery system is used to optimize replenishment for particular applications and environments. In some embodiments, different encapsulating liquids are added at different replenishment steps. In some embodiments, the encapsulating liquid is replenished with the same encapsulating liquid.

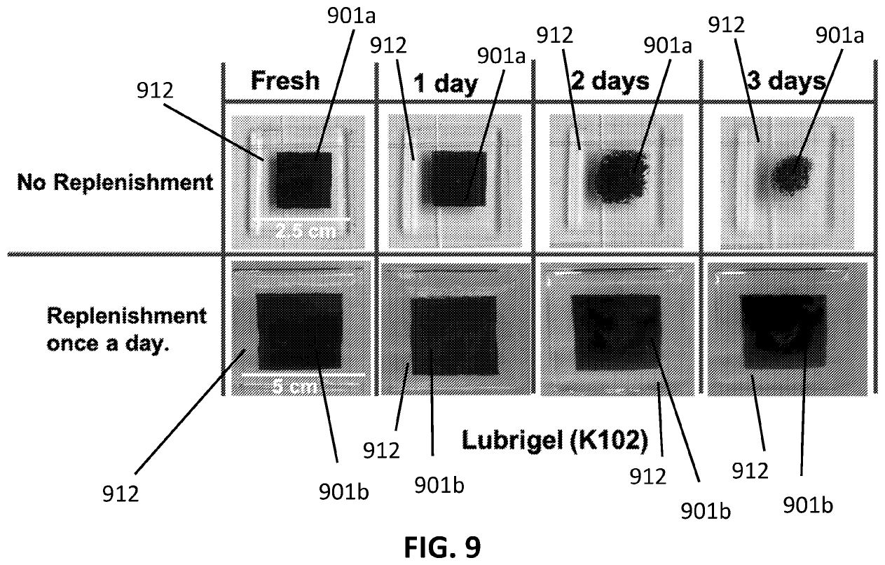

Both experiments and theory provide substantial evidence that this replenishment process is beneficial and increases the lifetime of an encapsulation device. For example, in one embodiment, shown in FIG. 9, the replenishment of the encapsulating liquid once a day led to very little degradation of an electronic device 901b after 3 days of immersion in water 912 (bottom view), whereas the same system without replenishment experienced advanced degradation of the electronic device 901a after three days immersed in water (top view). The electronic material is initially dark in color and turns lighter in color as it degrades. Experimental evaluation of replenishment is discussed in more detail in the Examples.

### 1. Mechanism of Water Removal by Replenishment

In some embodiments, replenishing the overlayer not only allows direct removal of water trapped in the encapsulating liquid but also induces any water molecules that may be present in an encapsulating liquid-infused polymer or porous material to diffuse out, driven by the concentration gradient. In some embodiments, the mechanism of water removal by replenishment is understood using a simple theoretical model: given the symmetries of the encapsulating liquid layer, a 1D model along the direction perpendicular to the surface is considered to numerically solve the diffusion equation.

In some embodiments, the encapsulation system includes a fluid delivery system to periodically replenish encapsulating liquid in a container. In some embodiments, the encapsulation system includes microfluidic channels with an input and an output in the container to recycle the encapsulating liquid and extract water from the encapsulating liquid.

According to this model, an encapsulation system with an encapsulating liquid-infused polymer is divided into two regions: a lubricant or encapsulating liquid overlayer, and an encapsulating liquid-infused polymer region. This model would be similar in a system with an encapsulating liquid-infused porous material. In this model, the boundary conditions are kept constant. At the interface between air and encapsulating liquid, the water concentration is equal to the maximum water concentration in the encapsulating liquid. On the other hand, the model assumes that upon contact with the highly water-sensitive encapsulated material, water will react immediately, and the local concentration of water at the surface of the encapsulated material is set to 0.

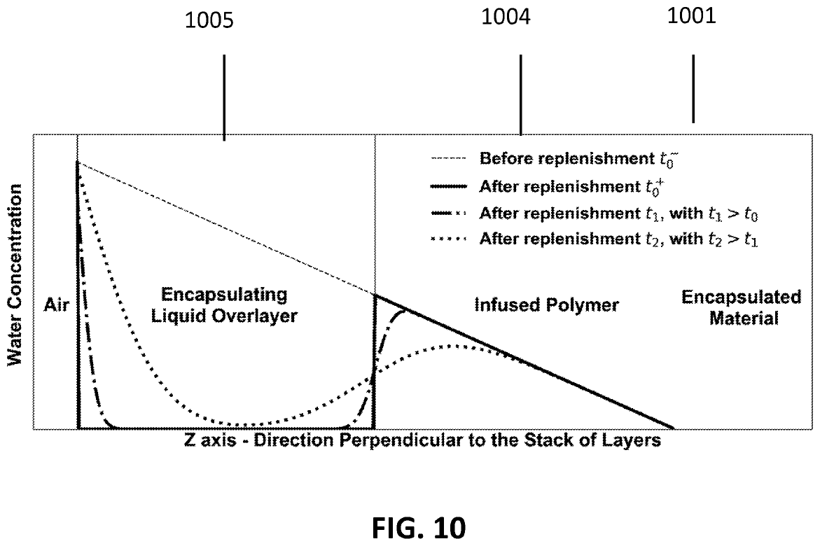

FIG. 10 shows a model of the water concentration as a function of distance across the encapsulation system (encapsulating liquid overlayer and encapsulating liquid-infused polymer layer) at different time points. Before replenishment, the encapsulation system has been exposed to air for a long period of time and water has had an opportunity to diffuse into the encapsulation system. At a time before replenishment (t₀⁻), shown by the dotted line, the water concentration decreases from a maximum value at the interface between air and encapsulating liquid, through the encapsulating liquid overlayer 1005 and the infused polymer layer 1004 until the water concentration reaches a value of zero at the surface of the encapsulated device or material 1001.

Upon replenishment (t₀⁺), shown by the black line, the local water concentration in the encapsulating liquid overlayer is reduced to zero, whereas the local water concentration in the encapsulating liquid-infused layer doesn't change immediately. At this time, the concentration in the encapsulating liquid-infused layer remains at its pre-replenishment state: decreasing from the value at the interface between the overlayer and infused layer to a value of zero at the surface of the encapsulated device. After replenishment, shown by the grey lines (t₁ and t₂), the water diffuses both from the interface between air and encapsulating liquid at one end, and at the interface between encapsulating liquid overlayer and encapsulating liquid-infused polymer at the other end. As seen in FIG. 10, after replenishment, water diffuses out of the infused layer into the overlayer due to a concentration gradient because the water concentration is lower in the overlayer 1001 than in the infused polymer layer 1004.

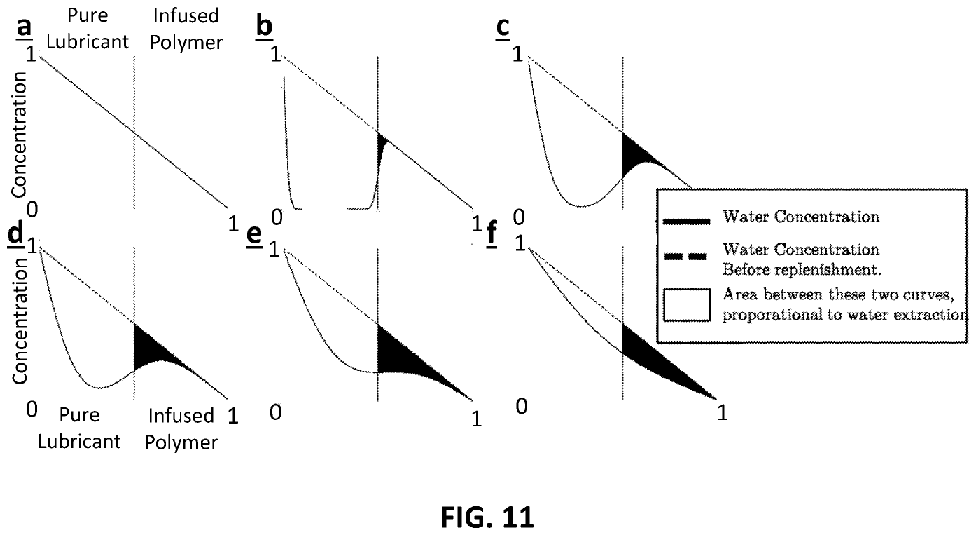

FIG. 11 (views a-f) shows the water concentration profile in the encapsulating liquid overlayer (pure lubricant) and in the infused polymer layers at different times after replenishment. Each successive graph shows the concentration profile at a later time point. The dotted line shows the water concentration in these regions immediately before replenishment, and the area between the curves in the infused layer shows the amount of water that has been removed from the infused polymer layer since replenishment. After replenishment, the infused polymer layer becomes a region of high water concentration compared replenished encapsulating liquid overlayer region. As a result, water “back-diffuses” from the encapsulating liquid-infused polymer region back into the encapsulated liquid overlayer region.

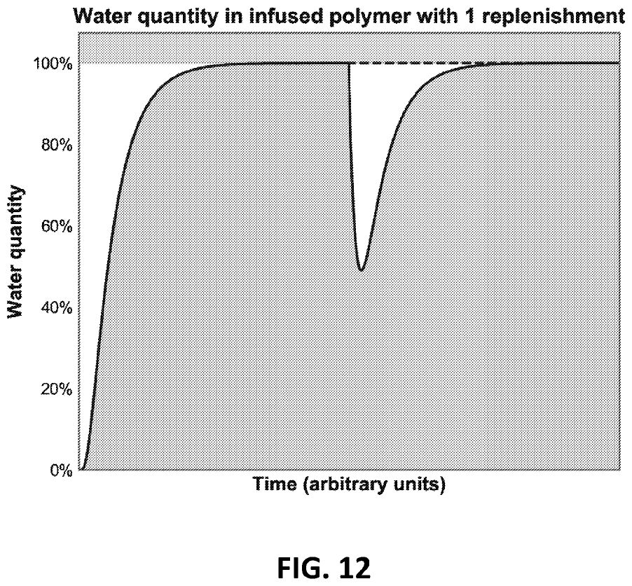

In some embodiments, by integrating the water concentration profile in the “infused polymer” region, one can obtain an estimate of the amount of water than is removed from the polymer region by replenishment. FIG. 12 shows the theoretical efficiency of the replenishment process. FIG. 12 shows the amount of water in the encapsulating liquid-infused polymer before and after replenishment, where the amount of water removed is equal to the area between the dotted line and the curve. For example, for an encapsulation system with a thickness that is half encapsulating liquid overlayer and half encapsulating liquid infused-polymer, one replenishment of the liquid layer removes up to 50% of the water content of the infused-polymer layer. In some embodiments, the percentage of water extracted will vary as a function of the ratio of the overlayer and infused polymer layer thicknesses. In some embodiments, the thicker the overlayer, the more water is extracted from the infused polymer layer. In some embodiments, the efficiency is tuned by tuning the relative thicknesses of the encapsulating liquid overlayer and encapsulating liquid-infused polymer or the properties of the encapsulating liquid or the polymer. In some embodiments, efficiency of replenishment is affected by quality of the replenishment process, crosslinking density of the polymer, pore size distribution of the polymer, conditions of the replenishment process, nature of the encapsulating liquid, and temperature.

### 2. Timing of Periodic Replenishment

In some embodiments, the frequency of replenishment plays a key role in preventing the WVTR from entering the steady region and preventing water from diffusing to the surface of the water-sensitive material. In some embodiments, replenishment occurs at periodic intervals. In some embodiments, replenishment occurs continuously.

The optimal timing of periodic replenishment is visualized using a colormap that stacks the water concentration profiles at each time point. Moreover, each value of the concentration profile is represented as a percentage of the final value obtained once the steady state diffusion regime is established. This percentage also represents the percentage of flux at the interface between the polymer and the encapsulated material. Thus, if the local water concentration at the interface between the infused polymer and the encapsulated material is reduced to 50% of the steady state diffusion value at a time point, the water vapor transport rate is reduced to 50% of the value obtained without replenishment.

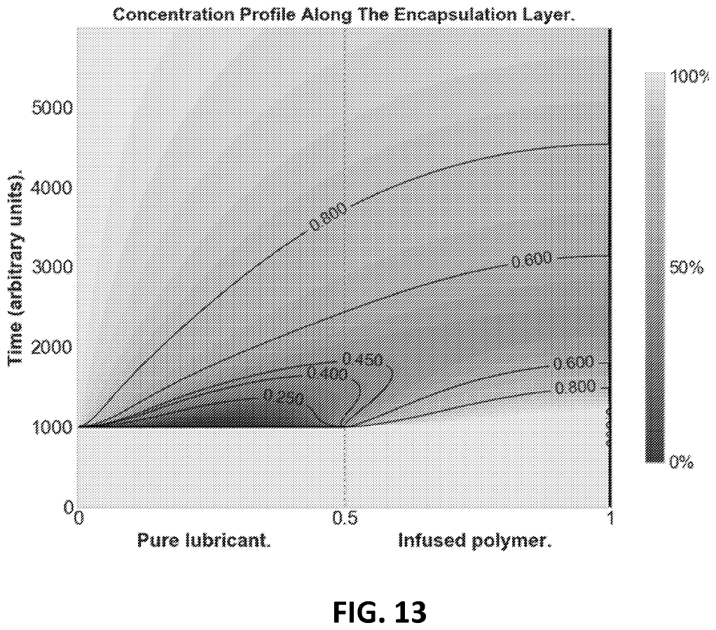

FIG. 13 shows the concentration profile for one replenishment occurring at t=1000 (arbitrary units). FIG. 13 shows the water concentration (greyscale intensity) along the thickness of the encapsulation layer (x-axis) at different times (y-axis). The local concentration is displayed as a percentage of its maximum local value. The replenishment happens at t=1000. The water vapor transport rate is read at x=1 at the interface between the infused polymer and the encapsulated material. By about t=3000, the water vapor transport rate is 0.6 of its maximum value at the interface between the polymer and the water-sensitive material (x=1). The water vapor transport rate at this interface reaches 0.8 of its maximum value between t=4000 and t=5000. FIG. 13 suggests that, in some embodiments, without additional replenishment, water can eventually diffuse to the water-sensitive material. In some embodiments, an encapsulating liquid extends the time for water to diffuse to an water-sensitive material compared to solid-state encapsulation. In some embodiments, the amount by which the time for water to diffuse is extended depends on the thickness of the encapsulating liquid layer. In some embodiments, the thicker encapsulating liquid overlayer, the longer it takes for water to diffuse. In some embodiments, diffusion time is proportional to the square of the thickness. For example, a two-fold increase in thickness results in a four-fold increase in time for water to diffuse. In some embodiments, at fixed infused polymer thickness, there is a two-fold increase in water diffusion time between a dry polymer and a liquid-infused polymer with Krytox 102 and Krytox 104.

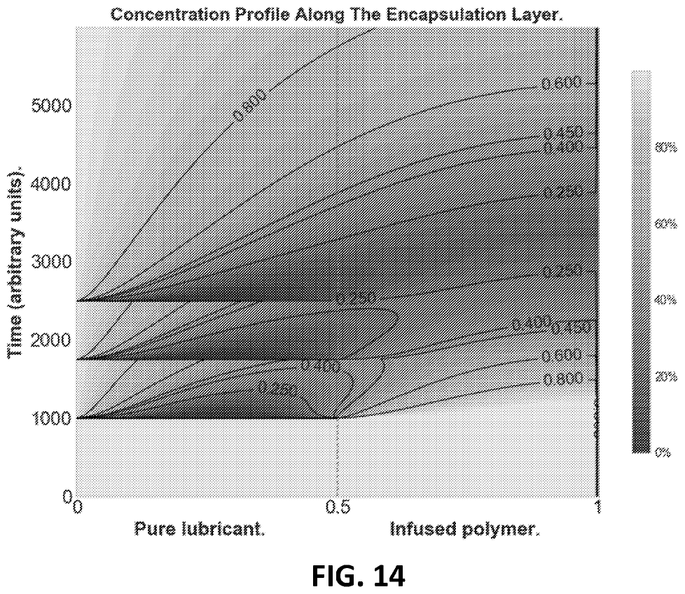

If the encapsulation system is replenished three times, the water vapor transport rate at the interface is decreased down to 20% of the maximum value before subsequent replenishment. FIG. 14 shows the water concentration (greyscale intensity) along the thickness of the encapsulation layer (x-axis) at different times (y-axis). The local concentration is displayed as a percentage of its maximum local value. Here, three consecutive replenishment happen at t=1000, t=2000, and t=3000. In some embodiments, y carefully choosing the replenishment frequency, the water vapor transport rate (or water flux) at the interface between the infused polymer and the active material (x=1) is kept below 25% of the maximum value at all times. By replenishing with sufficient frequency, it is possible to prevent diffusion of water vapor to the water-sensitive material.

In some embodiments, an optimal or sufficient frequency of periodic replenishment is determined theoretically using finite difference models. In some embodiments, a finite difference model solves differential equations by approximating them with difference equations. In other embodiments, an optimal or sufficient frequency of periodic replenishment is determined experimentally with simple WVTR measurements. In some embodiments, WVTR is measured using the electrical calcium test, which provides very accurate measurements of the WVTR. In some embodiments, water concentration is measured by performing a Karl-Fischer titration. Karl-Fischer titrations provide water trace measurements down to a couple of ppm.

In some embodiments, replenishment occurs when the water transport rate reaches about 10⁻⁵ g m⁻² per day for halide perovskite. In some embodiments, the encapsulating liquid is replenished once a day, once a week, or once month.

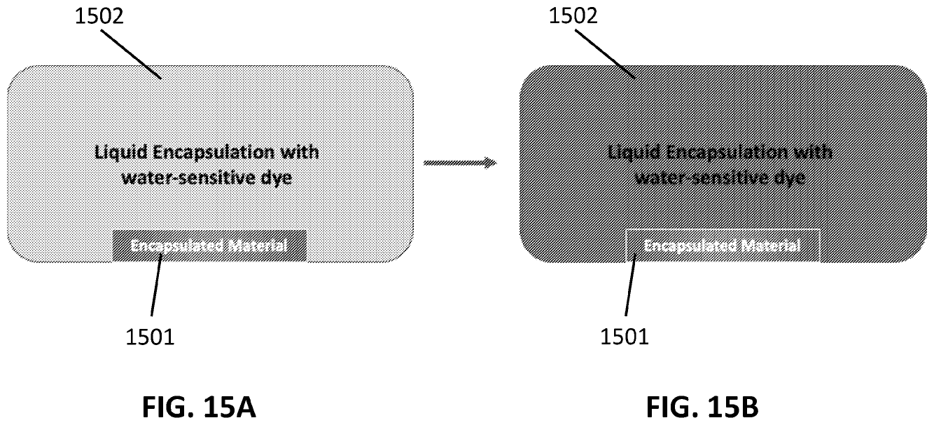

In some embodiments, the timing of replenishment is determined using a water-sensitive dye. In some embodiments, shown in FIGS. 15A-15B the encapsulating liquid 1502 contains a water-sensitive dye that changes color or other physical property when the concentration of water (or other undesired chemical) reaches a certain level and the encapsulating liquid needs to be changed/replenished/recycled. In one embodiment, FIG. 15A shows the liquid encapsulation in the initial stage, when the dye is, for example, transparent, and there is no need to replenish the encapsulating liquid 1502. In one embodiment, FIG. 15B shows that when the concentration of water (or any other undesired chemical) reaches a critical level, the dye changes color, and the user then knows it is time to replenish the encapsulating liquid 1502. In this embodiment, the encapsulating liquid 1502 is replenished with sufficient frequency to avoid diffusion of water to the encapsulated material 1501.

In some embodiments, the encapsulation system incorporates a water-sensitive dye that would turn to a certain color when the encapsulation liquid needs to be replenished (e.g., a chemical dye that is initially transparent and turns red when the liquid encapsulation needs to be replenished). In some embodiments, the encapsulation device should be replenished when the water concentration reaches a certain level. In some embodiments, this design helps the user know when the encapsulating liquid needs to be replenished.

In some embodiments, the dye is a chemical compound or even a biological compound. In some embodiments, the dyes are miscible in the encapsulating liquid. For example, perylene is miscible in alkanes. In some embodiments Bodipy dyes are chemical dyes used for staining biological membranes that are be used in encapsulating liquids with similar chemistry. In some embodiments, these dyes are very sensitive to water or any undesired chemical to indicate a need to replenish the encapsulating liquid.

### 3. Delivery System for Replenishment of the Encapsulating Liquid

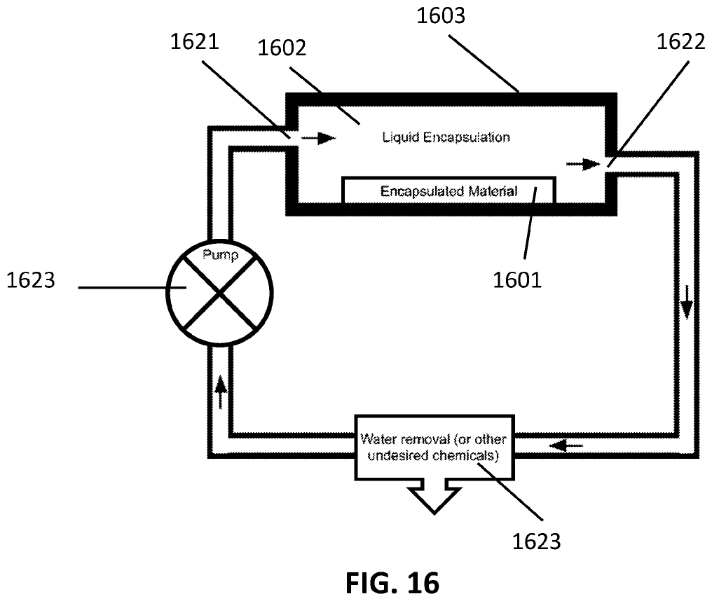

In some embodiments, shown in FIG. 16, an encapsulation system allows for periodic replenishment over a long period of time. In some embodiments, the encapsulated material or device 1601 and encapsulating liquid 1602 are contained in container 1603 with an inlet 1621 that provides the encapsulation system with new, fresh, and water-free encapsulating liquid, and an outlet 1622 that collects and removes the old, water-containing encapsulating liquid. In some embodiments, the encapsulated liquid circulates through a closed circuit to be recycled once it passes through a “water removal” unit 1623 that removes the water from the water-containing encapsulating liquid and reinjects it back into the circuit. In some embodiments, water is removed by a filter or membrane. In some embodiments, water is removed by an active component or living liquid encapsulation, as described below. In some embodiments, the system includes container 1603 for the encapsulated material 1601, and the container 1603 includes an inlet 1621 and an outlet 1622. In some embodiments, the system includes a pump 1624 to move encapsulating liquid 1602 through the circuit. In some embodiments, encapsulating liquid that contains water is removed from a container 1603 containing the encapsulated material through an outlet 1622 and moved through a water removal unit 1623. After moving through the water removal unit, the now water-free encapsulating liquid 1602 returns to a container containing the encapsulated material through an inlet 1621.

### E. Multi-Layered Encapsulating Liquids

In some embodiments, the encapsulating system is multi-layered and includes a plurality of encapsulating liquids with different properties that form multiple layers. In some embodiments, different encapsulating liquids provide different macroscopic properties, including water vapor transport rate, thermal transport, absorbance spectrum, chemical stability, or mechanical properties. In some embodiments, multi-layered encapsulating devices allow for greater design flexibility: instead of having to choose a single encapsulating liquid, different encapsulating liquids are combined and the encapsulation system benefits from their respective properties. In some embodiments, multi-layered systems make it possible to tune the properties of the surface layer without substantially increasing the water vapor transport rate through the encapsulation layer as a whole. For example, the top layer is tuned to have properties optimized for slipperiness or self-cleaning, while the bottom layer adjacent to the water-sensitive material is tuned to have properties optimized for prevention of water diffusion. For example, in one embodiment, a multilayered system includes one layer of fluorinated polymer (dense), one layer of mineral oil, and one layer of alkane. In some embodiments, the range of chemicals whose diffusions are prevented is increased.

In some embodiments, different encapsulating liquid viscosities and densities provide different properties. For example, low viscosity liquids are easier to circulate through microfluidics channels, but are less efficient at preventing water diffusion. In some embodiments, multi-layered system includes a low viscosity encapsulating liquid disposed above a higher viscosity encapsulating liquid with a low water vapor transport rate. In this embodiment, the higher viscosity encapsulating liquid is adjacent to the water-sensitive material. In this embodiment, the low viscosity encapsulating liquid is replenished easily to maintain a concentration gradient that encourages extraction of water molecules from the higher viscosity encapsulation liquid adjacent to the water-sensitive material.

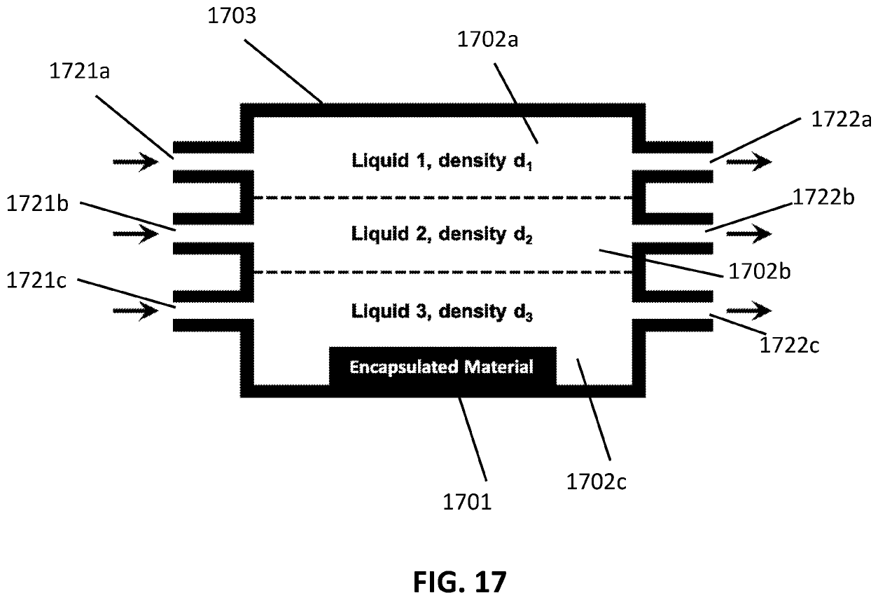

In one embodiment, shown in FIG. 17, immiscible liquids with different densities are used to maintain separate layers along the height of a container 1703. In this embodiment, the encapsulating liquids 1702a, 1702b, 1702c have increasing densities from the top of the container to the bottom of the container. In this embodiment, the container includes a plurality of inlets 1721a, 1721b, 1721c and outlets 1722a, 1722b, 1722c at different heights corresponding to each encapsulating liquid 1702a, 1702b, 1702c. In this embodiment, each inlet and outlet replenishes a specific encapsulation liquid. In some embodiments, encapsulating liquids 1702a, 1702b with lower densities also have lower viscosities and are recycled more easily through fluidic channels. In some embodiments, the encapsulating liquid 1702c closest to the water-sensitive material 1701 is selected to minimize water diffusion.

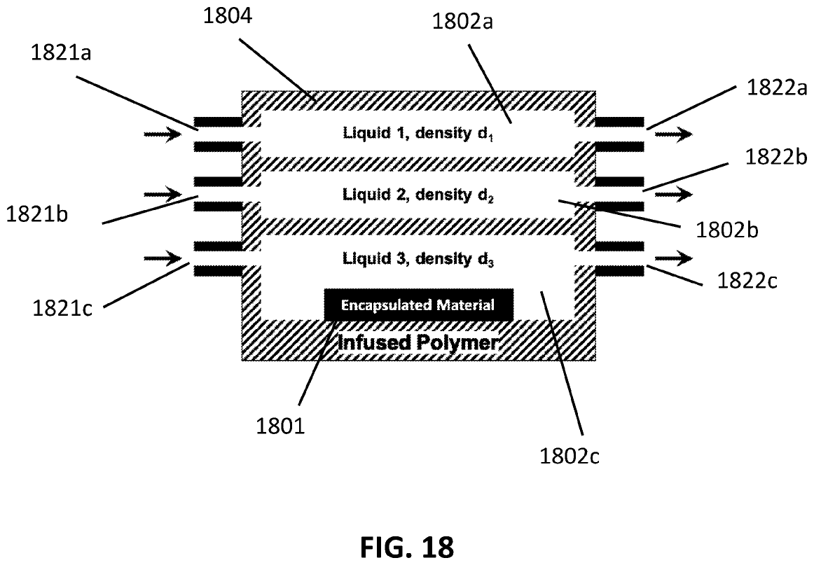

In some embodiments, shown in FIG. 18, a liquid-infused polymer 1804 is used to contain and separate a plurality of encapsulating liquids 1802a, 1802b, 1802c. In some embodiments, the liquid infused polymer forms a physical layer between encapsulating liquids that allows the use of miscible liquids with different viscosities but similar densities. In some embodiments, the container is made of liquid-infused polymer, allowing greater mechanical flexibility and transparency than solid state containers made of glass or plastic. In some embodiments, the polymer includes a plurality of inlets 1821a, 1821b, 1821c and outlets 1822a, 1822b, 1822c at different heights for each for each of the encapsulating liquids 1802a, 1802b, 1802c. In this embodiment, each inlet and outlet replenishes a specific encapsulation liquid. In some embodiments, each encapsulating liquid layer includes a different infused polymer adapted to the corresponding encapsulating liquid.

### F. Living Liquid Encapsulations

In some embodiments, the encapsulation system includes active or living liquid encapsulations with active components. In some embodiments, these active components are capable of converting unwanted water or gas molecules into useful resources. In some embodiments, the useful resources include carbon oils, ammonia, and hydrogen. In the some embodiments, the active components generate fresh encapsulating liquid for replenishment of the encapsulation system. In some embodiments, the active components are living microorganisms. In some embodiments, the active components are inorganic semiconductors.

1. Encapsulation Systems with Living Microorganisms

In some embodiments, the encapsulation system includes living microorganisms. In some embodiments, the liquid environment allows this encapsulation system to incorporate living microorganisms that converts unwanted water or other gas molecules (e.g., CO₂, N₂ and O₂) to useful resources such as carbon oils, ammonia, and hydrogen. In some embodiments, living organisms are part of a highly multifunctional encapsulation system that operates to replenish the encapsulating liquid, and living organisms serve as an active component that contributes to the efficiency of the system. In some embodiments, through choosing different living organisms, different chemicals are generated or eliminated.

In some embodiments, the microorganisms are in an aqueous liquid. In some embodiments, the products of the microorganisms are oils, and these products diffuse into a hydrophobic encapsulating liquid layer. In some embodiments, the microorganisms live in a separate container and the formed oil seeps into/onto the container with the encapsulating liquid and encapsulated material to replenish the encapsulating liquid. In some embodiments, organisms turn water and other chemicals from the environment into useful compounds, such as new encapsulating liquid molecules. In some embodiments, microorganisms also convert water and other chemicals into active molecules beneficial for the encapsulated material.

In some embodiments, microalgae convert plant oils into glycerol and biodiesel (e.g., methyl esters). In some embodiments, algae produce lipids, hydrocarbons, and other complex oils. Non-limiting examples of microalgae that make oils include Botryococcus braunii, Chlorella sp., Crypthecodinium cohnii, Cylindrotheca sp.,

Dunaliella primolecta, Isochrysis sp., Monallanthus salina, Nannochloris sp., Nannochloropsis sp., Neochloris oleoabundans, Nitzschia sp., Phaeodactylum tricornutum,

Schizochytrium sp., and Tetraselmis sueica.

In some embodiments, the lithoautotrophic microorganism Ralstonia eutropha H16 produced isobutanol using carbon dioxide and electricity. In some embodiments, the oil-producing bacteria Origanum vulgare produced n-alkanes. In some embodiments, photobioreactors provide a controlled environment that is tailored to the specific demands of highly productive microalgae to attain a consistently good annual yield of oil. In some embodiments, the function of solar batteries is linked with the photobioproduction of encapsulating oils. In some embodiments, the encapsulation system includes additional biotechnology modules where microorganisms are stored and these reactions take place. In some embodiments, photosynthesis turns water and carbon dioxide into chemical energy. In some embodiments, a genetically modified microorganism uses photosynthesis within the encapsulation layer

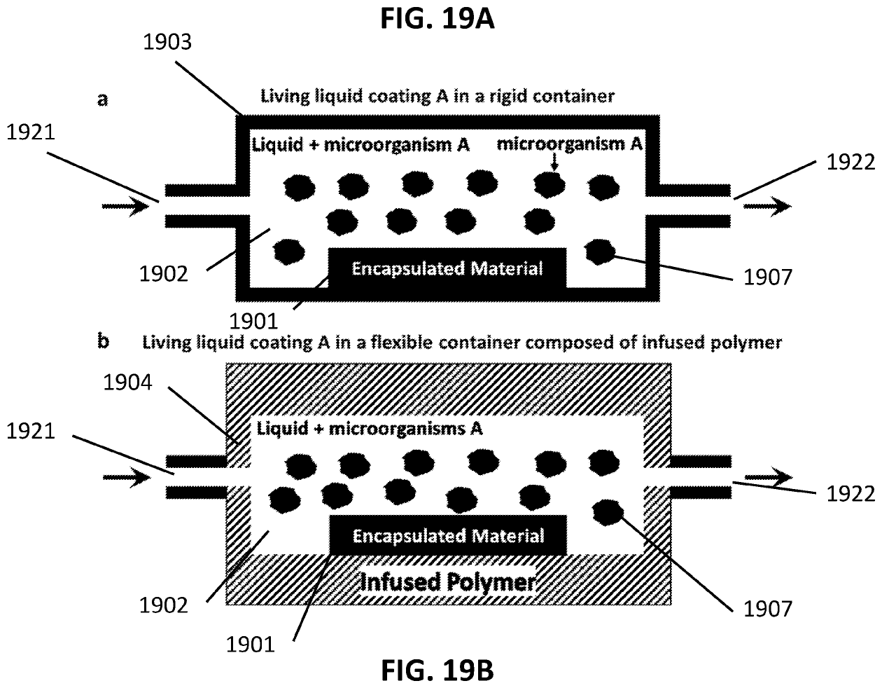

In one embodiment, shown in FIGS. 19A-19B, a microorganism A 1907 converts H₂O and CO₂ to carbon oil through photosynthesis. In this embodiment, the encapsulation becomes self-replenishing. FIG. 19A shows a schematic of living liquid coating A in a rigid container 1903. In this embodiment, the rigid container 1903 contains the encapsulated material 1901, the encapsulating liquid 1902, and the microorganism A 1907. FIG. 19B shows a schematic of living liquid A in a flexible container composed of infused polymer 1904. In this embodiment, the infused polymer 1904 contains the encapsulated material 1901, the encapsulating liquid 1902, and the microorganism A 1907. In some embodiments, the container, whether rigid or flexible, includes an inlet 1921 and an outlet 1922 for replenishing the encapsulating liquid 1902. In some embodiments, the microorganism A 1907 absorbs H₂O and CO₂, and produces oil through photosynthesis.

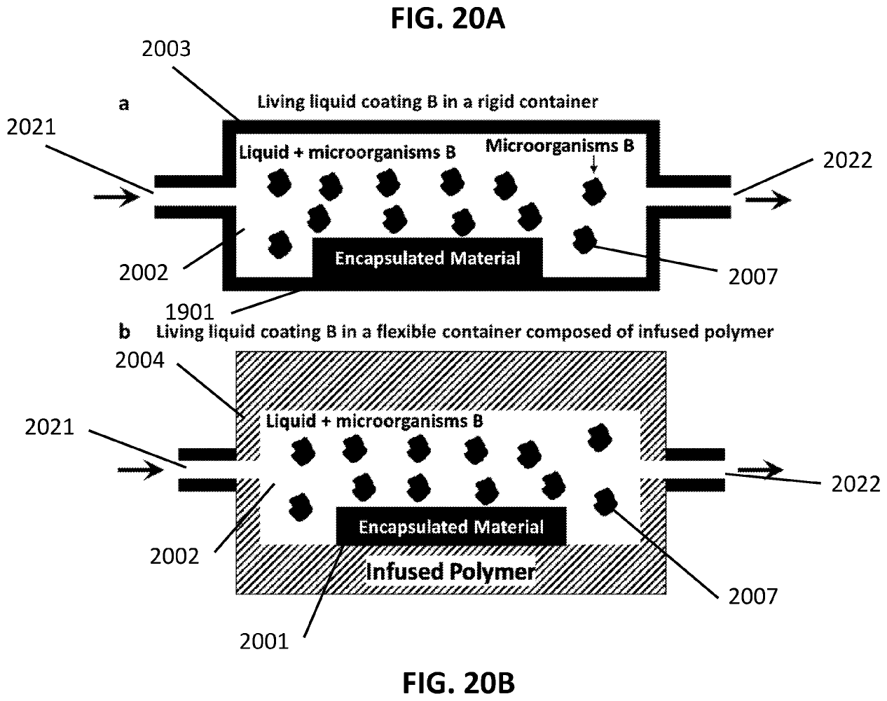

In one embodiment, shown in FIG. 20A-20B, the liquid contains microorganism B 2007 that absorbs H₂/H₂O and N₂, and produces NH₃, through a fixation process. FIG. 20A shows a schematic of living liquid coating B in a rigid container 2003. In this embodiment, the rigid container 2003 contains the encapsulated material 2001, the encapsulating liquid 2002, and the microorganism B 2007. FIG. 20B shows a schematic of living liquid coating B in a flexible container composed of infused polymer 2004. In this embodiment, the infused polymer 2004 contains the encapsulated material 2001, the encapsulating liquid 2002, and the microorganism B 2007. In some embodiments, the container, whether rigid or flexible, includes an inlet 2021 and an outlet 2022 for replenishing the encapsulating liquid 2002. In some embodiments, microorganism B 2007 absorbs H₂/H₂O and N₂, and produces NH₃. In some embodiments, phytoplankton in the oceans absorbs hydrogen and nitrogen to produce ammonium.

2. Encapsulation Systems with Inorganic Semiconductors

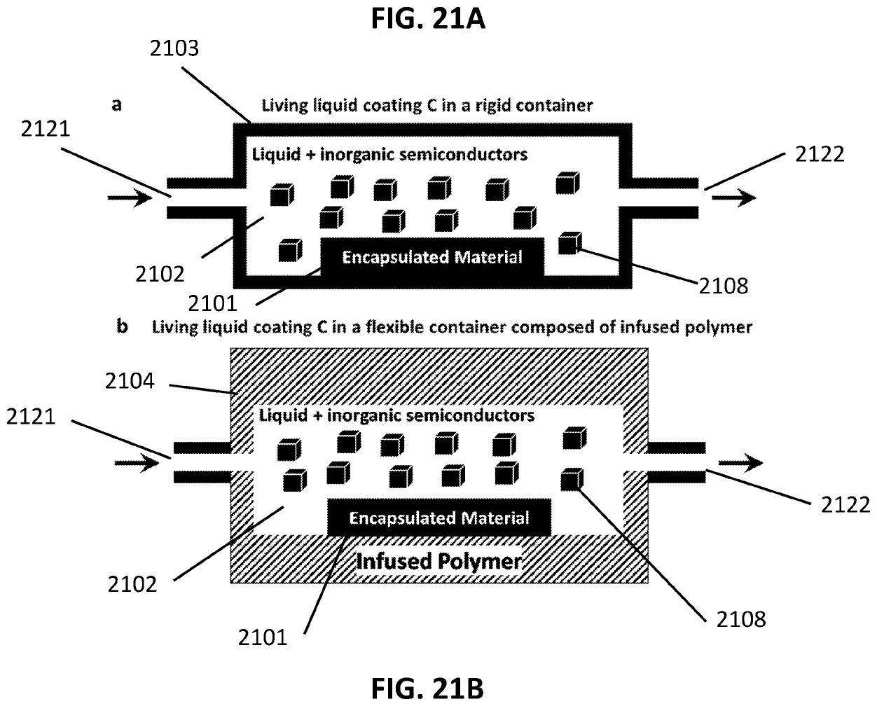

In one embodiment, shown in FIGS. 21A-21B, the liquid contains inorganic semiconductors that split H₂O into H₂ and O₂ through artificial photosynthesis. In some embodiments, semiconductors are suspended in the encapsulating liquid if both sides of the container are exposed to air or harmful chemicals. In some embodiments, for example, solar cell applications, the semiconductors attach to a side of the container that is not exposed to ambient air or harmful chemicals. In some embodiments, the inorganic materials are titania microparticles, which disassociate water into hydrogen and oxygen with sunlight. In some embodiments, for example, fuel cells and photoelectrochemical cells, inorganic semiconductors not only serve a function for encapsulation, but also a functional component to improve the fuel utilization/production efficiency.

FIG. 21A shows a schematic of living liquid coating C in a rigid container 2103. In this embodiment, the rigid container 2103 contains the encapsulated material 2101, the encapsulating liquid 2102, and the inorganic semiconductors 2108. FIG. 20B shows a schematic of living liquid coating C in a flexible container composed of infused polymer 2104. In this embodiment, the infused polymer 2104 contains the encapsulated material 2101, the encapsulating liquid 2102, and the inorganic semiconductors 2108. In some embodiments, the container, whether rigid or flexible, includes an inlet 2121 and an outlet 2122 for replenishing the encapsulating liquid 2102. In some embodiments, the liquid contains inorganic semiconductors 2108 that split H₂O into H₂ and O₂ with the help of sunlight. In some embodiments, inorganic semiconductors include electrolytic cells that would split water in situ under the application of an electric current.

### 3. Multilayered Living Liquid Encapsulations

In some embodiments, living liquids are combined with multilayered encapsulation systems. In some embodiments, the living organisms are capable of living in only certain specific layers. In some embodiments, multi-layered systems make replenishment of layer with microorganisms easier to control. In some embodiments, sandwiching microorganisms between two layers that preventing the development of microorganisms prevents the attachment of these organisms to the container walls. In some embodiments, microorganisms coexist in the same layer as a semiconductor if there is no negative interaction between the microorganism and the semiconductors. In some embodiments, a layer that is unattractive to the microorganisms prevents diffusion of microorganisms into a layer that includes the semiconductors.

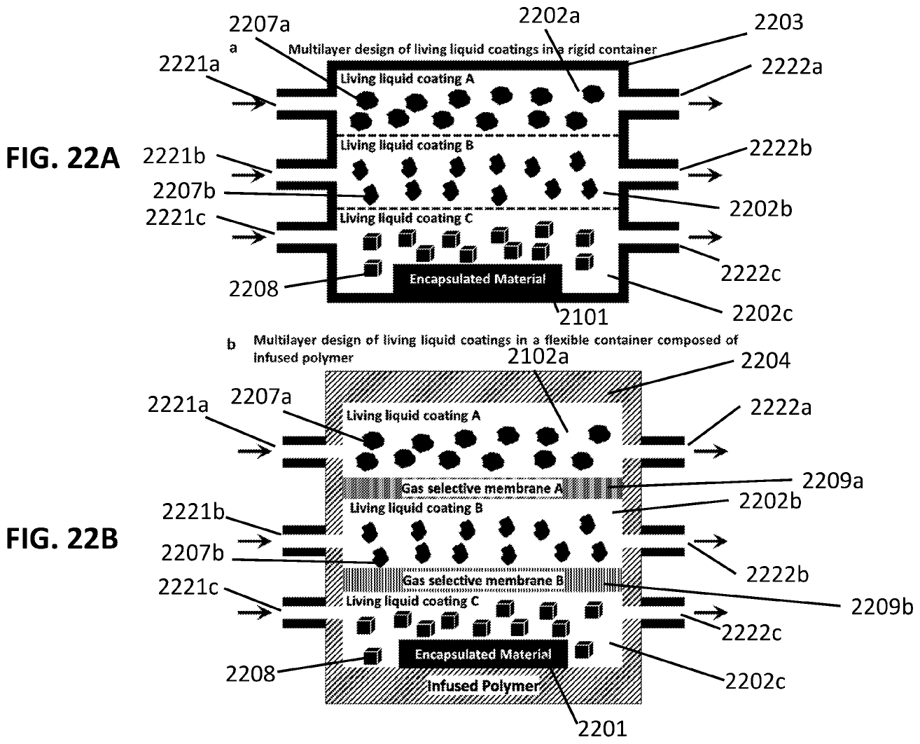

In some embodiments, shown in FIGS. 22A-22B, a living encapsulation is combined with a multilayer design. In some embodiments, the sequence of the liquid coatings is mixed and matched according to the encapsulated material and operational condition. In one embodiment, shown in FIGS. 22A-22B, the first layer (living liquid coating A) includes a first encapsulating liquid 2102a and a first microorganism 2207a, the second layer includes a second encapsulating liquid 2102b and a second microorganism 2207b (living liquid coating B), and the third layer includes a third encapsulating liquid 2202c and an inorganic semiconductor 2208 (living liquid coating C). In some embodiments, all layers could contain the same encapsulating liquid. In this embodiments, the multilayer architecture achieve thicker encapsulation devices using only soft polymer and encapsulating liquids that would otherwise deform due to gravity if the system was composed of one single thick layer. In some embodiments, each layer contains a different encapsulating liquid.

In some embodiments, FIG. 22A shows a schematic of a multilayered living liquid encapsulation system in a rigid container 2203. In this embodiment, the rigid container 2203 contains the encapsulated material 2201, a plurality of encapsulating liquids 2202a, 2202b, 2202c, and a plurality of microorganisms 2207a, 2207b, and/or inorganic semiconductors 2208. In some embodiments, the container 2203 includes a plurality of inlets 2221a, 2221b, 2221c, and outlets 2222a, 2222b, 2222c, each associated with one of the encapsulating liquids 2202a, 2202b, 2202c and respective living liquid layers for replenishing the encapsulating liquids.

In some embodiments, FIG. 22B shows a schematic of a multilayered living liquid encapsulation system in a flexible container composed of an infused polymer 2204. In some embodiments, the infused polymer forms a physical barrier between the layers of the encapsulation system. In this embodiment, the infused polymer 2204 contains the encapsulated material 2201, a plurality of encapsulating liquids 2202a, 2202b, 2202c, and a plurality of microorganisms 2207a, 2207b, and/or inorganic semiconductors 2208. In some embodiments, the infused polymer 2203 includes a plurality of inlets 2221a, 2221b, 2221c, and outlets 2222a, 2222b, 2222c, each associated with one of the encapsulating liquids 2202a, 2202b, 2202c and respective living liquid layers for replenishing the encapsulating liquids. In some embodiments, the infused polymer between each layer is a gas selective membrane 2209a, 2209b. For example, as shown in FIG. 22B, the membrane B 2209b selectively transports hydrogen produced by inorganic semiconductors from the coating C (which includes a third encapsulating liquid 2202c and inorganic semiconductors 2208) to the coating B (which includes a second encapsulating liquid 2202b and a second microorganism 2207b). In this embodiment, the microorganism B 2207b in the coating B thus uses the hydrogen to produce ammonia.

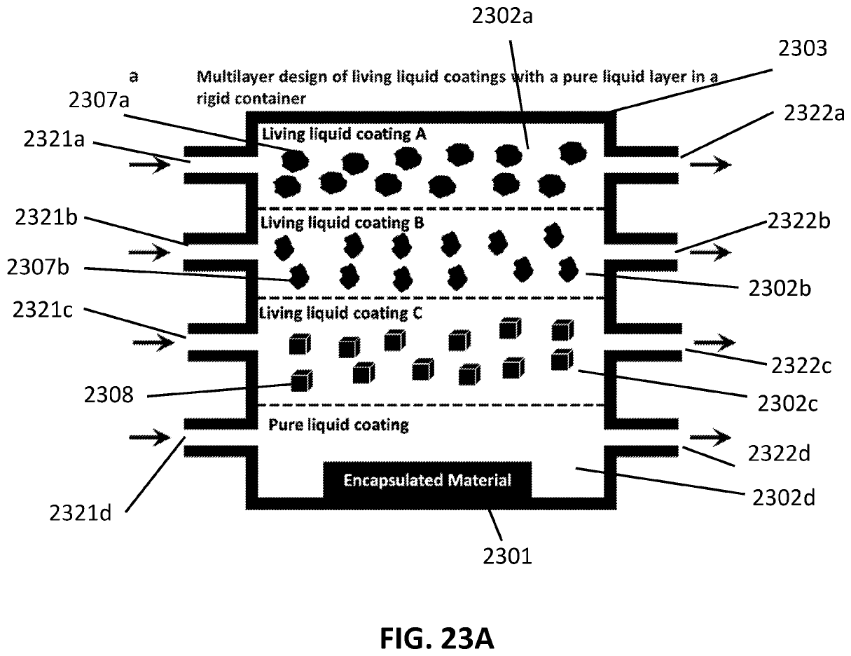

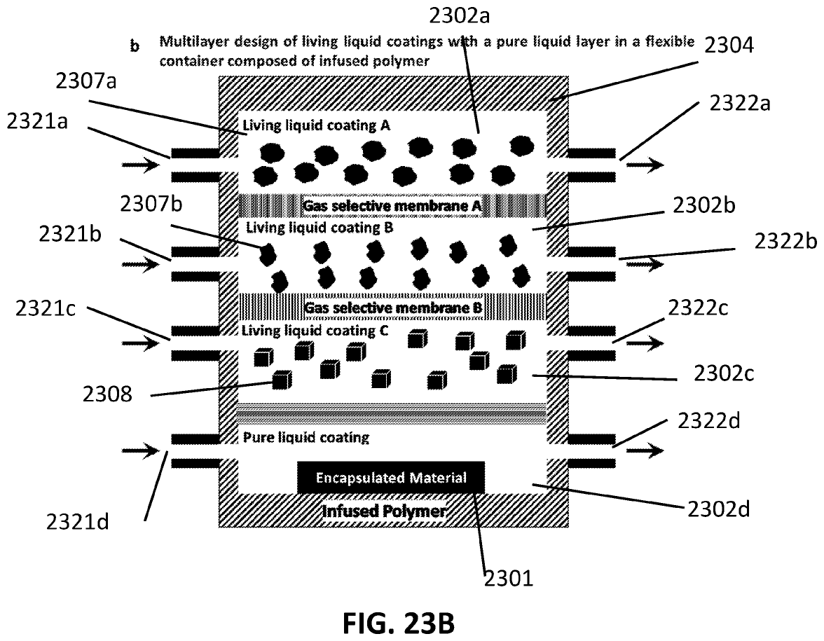

In some embodiments, shown in FIGS. 23A-23B, if the encapsulated target is sensitive to the living organisms or inorganic semiconductor, the multilayered encapsulation system includes a pure encapsulating liquid coating in between the encapsulated material 2301 and the microorganisms or semiconductors. In one embodiment, shown in FIGS. 23A-23B, the first layer (living liquid coating A) includes a first encapsulating liquid 2302a and a first microorganism 2307a, the second layer includes a second encapsulating liquid 2302b and a second microorganism 2307b (living liquid coating B), the third layer includes a third encapsulating liquid 2302c and an inorganic semiconductor 2308 (living liquid coating C), and the fourth layer includes a fourth encapsulating liquid 2202d and the encapsulated material 2301. In some embodiments, FIG. 23A shows a schematic of multilayer living encapsulations with a pure encapsulating liquid 2302d coating in a rigid container 2303. In some embodiments, the container 2303 includes a plurality of inlets 2321a, 2321b, 2321c, 2321d, and outlets 2322a, 2322b, 2322c, 2322d, each associated with one of the encapsulating liquids 2302a, 2302b, 2302c, 2302d and respective living liquid layers for replenishing the encapsulating liquids. In some embodiments, FIG. 23B shows a schematic of multilayer living encapsulations with a pure encapsulating liquid 2302d coating in a flexible container composed of an infused polymer 2304. In some embodiments, the infused polymer 2304 includes gas-permeable membranes 2309a, 2309b, 2309c between each layer. In some embodiments, the infused polymer 2304 includes a plurality of inlets 2321a, 2321b, 2321c, 2321d, and outlets 2322a, 2322b, 2322c, 2322d, each associated with one of the encapsulating liquids 2302a, 2302b, 2302c, 2302d and respective living liquid layers for replenishing the encapsulating liquids.

### III. EXAMPLES

### A. Effect of Viscosity of Encapsulating Liquid on Water Transport

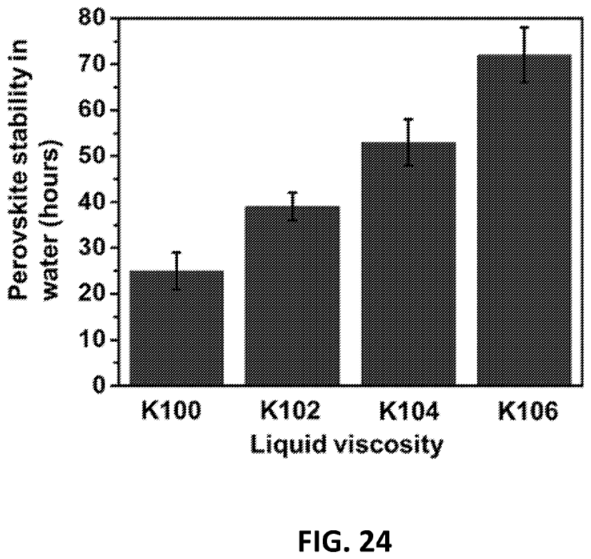

In one example, FIG. 24 shows the stability of perfluoropolyether-encapsulated perovskite as a function of perfluoropolyether viscosity. In this example, the halide perovskite was encapsulated by a copolymer of perfluoropolyether (PFPE) and 2-perfluorooctylethyl acrylate (PFOEA) which were infused with liquids of different viscosities. In this embodiment, high-viscosity perfluoropolyether liquid (Krytox 106, 1400 cSt) was able to stabilize halide perovskites three-times longer than low-viscosity perfluoropolyether liquid (Krytox 100, 12 cSt) when the perovskite was immersed in a water bath. The viscosity of K102 is 36 cSt at 0° C., and the viscosity of K104 is 180 cSt at 0° C.

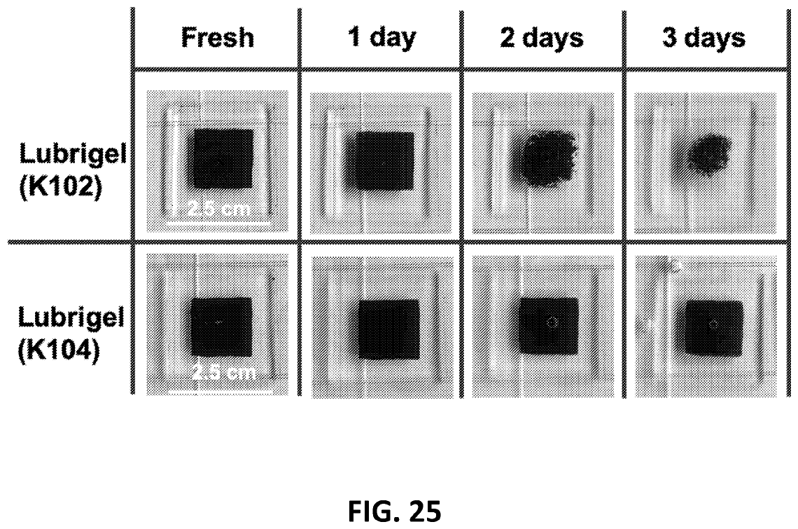

Similarly, as shown in FIG. 25, the viscosity of the encapsulating liquid used in an infused polymer system will have an impact on the deterioration of an encapsulated perovskite. In this experiment, perovskite was coated with the same PFPE-PFOEA copolymer system with constant thickness (about 300 μm) but infused with different encapsulating liquids, K102 and K104, of similar densities but different viscosities. In this example, the viscosity of K102 at room temperature is about 5 times lower than the viscosity of K104. As shown in FIG. 25, the higher the viscosity of the encapsulating liquid, the less the perovskite deteriorates over time. The higher encapsulating liquid viscosity (K104) prevented deterioration for three days, even though the intake of the encapsulating liquid by the polymer decreases with increasing viscosity. In contrast, the perovskite infused with the lower viscosity encapsulating liquid (K102) showed deterioration within two days. Therefore, the liquid viscosity, which contributes to a local degree of molecular constraining, plays an important role in preventing water from diffusing through the encapsulating liquid. Although early molecular dynamics simulations show that the diffusion of single water molecules is barely affected by the viscosity, water diffuses as clusters in the encapsulating layer. Water clusters diffuse more slowly than single water molecules. These results suggest that the encapsulating liquid viscosity affects the water cluster size distribution, which in turn affects the overall water diffusion coefficient.

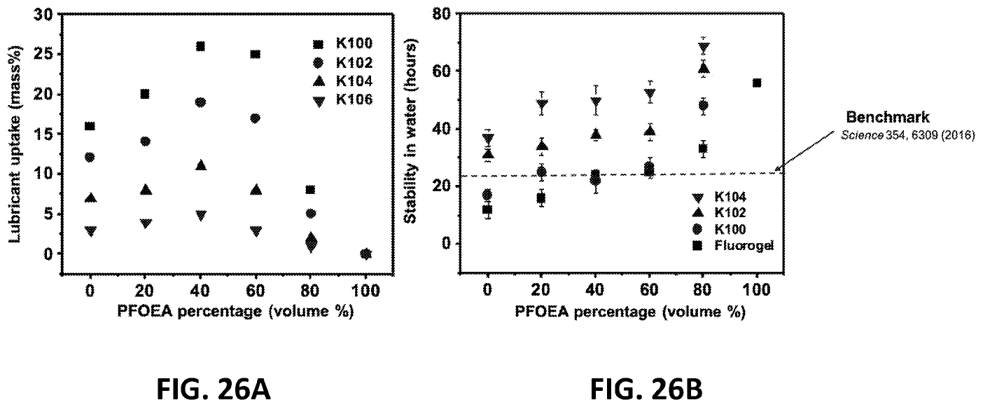

FIG. 26A shows performance of copolymers with different PFOEA/PFPE ratios when infused with different lubricants (K100, 102, 104, 106) of increasing viscosity but similar density. FIG. 26A shows that the lubricant uptake of the lower viscosity K100 and K102 is greater than K104 for each systems. However, as shown in FIG. 26B, the stability of the encapsulated perovskite in water is greater with the higher viscosity K104 than with K102 or K100. These results suggest that encapsulating liquid viscosity, or local constrained dynamics, plays an important role in preventing water diffusion.

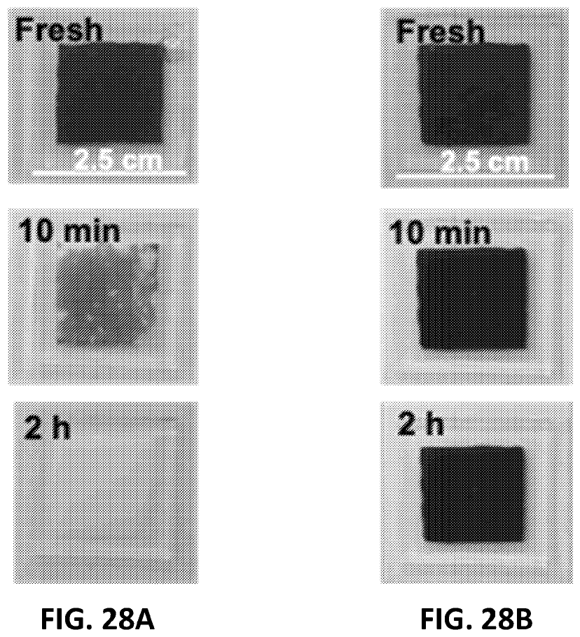

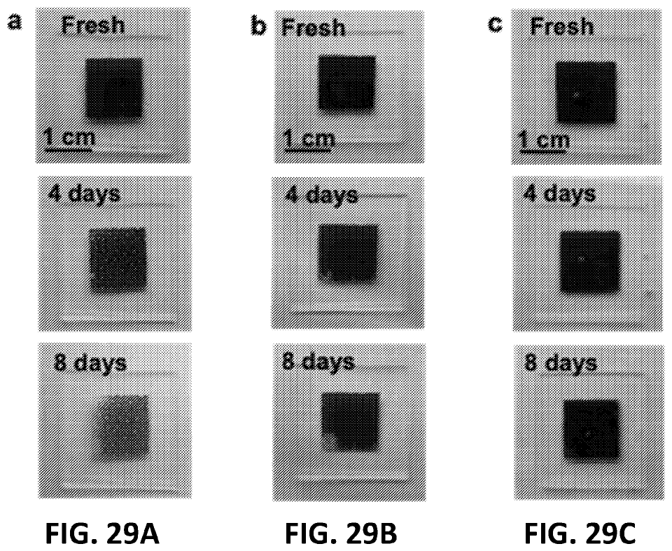

FIGS. 29A-29C show the effect of liquid viscosity for a crosslinked fluorinated polymer matrix used as an encapsulation layer of halide perovskite thin films. FIG. 29A shows a dry crosslinked fluorinated polymer matrix (fluorogel)-coated halide perovskite thin film immersed in water. FIG. 29B shows a low-viscosity oil-infused (DuPont Krytox GPL 102), crosslinked fluorinated polymer matrix (fluorogel)-coated halide perovskite thin film immersed in water. FIG. 29C shows a high-viscosity oil-infused (DuPont Krytox GPL 107), crosslinked fluorinated polymer matrix (fluorogel)-coated halide perovskite thin film immersed in water. The fluorogel infused with low viscosity oil, shown in FIG. 29B, showed some deterioration after 8 days, but showed reduced deterioration relative the fluorogel without oil, shown in FIG. 29A. The fluorogel infused with high viscosity oil, shown in FIG. 28C, achieved about 8 days stability in liquid water with a one-time overlayer replenishment. Previous reports have indicated that a 1-hour continuous immersion in water is roughly equivalent to about 180 hours of stability in air. This suggests the oil-infused fluorogel could theoretically provide over 4 years of stability in air. This value largely exceeds the current outdoor-stability benchmark for perovskite lifetime (about one day in water, and half a year in air) and approaches the commercial requirement (over 20 days in water, and 10 years in air).

### B. Pinning of Water Droplets by the Encapsulating Liquid

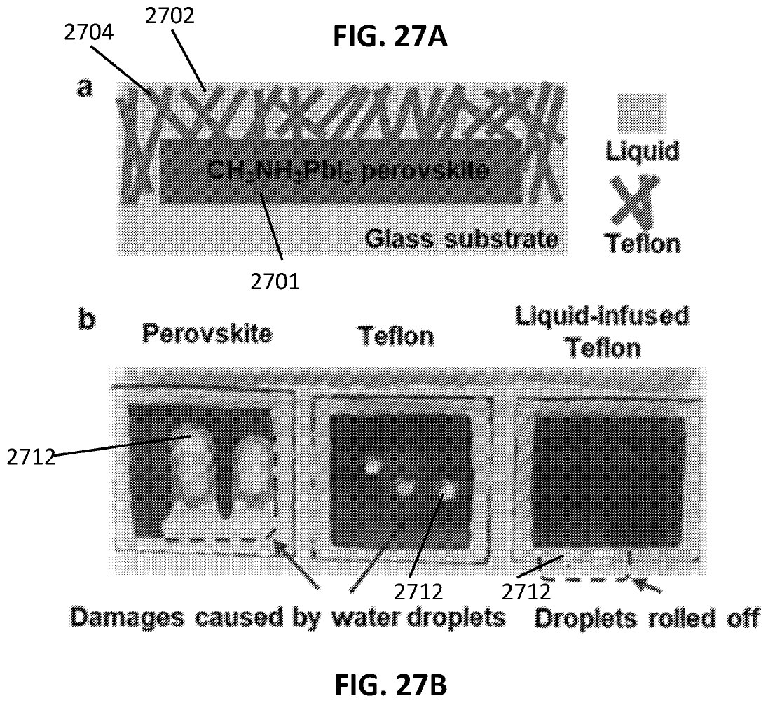

FIGS. 27A-27B show the encapsulation performance of a solid Teflon thin film was compared with a hydrophobic encapsulating liquid-infused Teflon film. In this example, the hydrophobic encapsulating liquid is a perfluoropolyether lubricant, DuPont Krytox® GPL 107 (density=1.95 g/mL, dielectric constant=2.1, kinematic viscosity=1600 cSt). The liquid-infused design is shown in FIG. 27A. FIG. 27A shows a cross-section of a perovskite film 2701 with a Teflon® polymer coating 2704 infused with an encapsulating liquid 2702.

FIG. 27B shows the surface of uncoated perovskite, Teflon®-coated perovskite, and liquid-infused Teflon®-coated perovskite. These surfaces are shown 6 minutes after contact with 5 μL water droplets 2712 while the surfaces were tilted at a 30° angle from the horizontal. As shown in FIG. 27B (left), The unprotected perovskite decomposed instantaneously when exposed to a small water droplet (5 μm), as indicated by the color change from dark to light. As shown in FIG. 27B (center), the Teflon® thin film without lubricant (considered a superhydrophobic surface) prevented the instantaneous degradation of perovskite, but the droplet remained pinned on the Teflon® surface. The pinned droplet allowed water molecules to gradually permeate the Teflon® through Brownian motion and eventually decompose the perovskite within 6 minutes of pinning. As shown in FIG. 27B (right), in contrast, the encapsulating liquid-infused Teflon® surface shed the water droplet and the perovskite remained intact.

### C. Effect of Replenishment of Encapsulating Liquid

FIG. 9 shows the effect of replenishment of the encapsulating liquid on perovskite deterioration. FIG. 9 (top) shows liquid infused-polymer encapsulated perovskite 901a without replenishment and FIG. 9 (bottom) shows liquid infused-polymer encapsulated perovskite 901b with replenishment. Perovskite is a water-sensitive material that is initially black but turns lighter in color when damaged. The perovskite is encapsulated with a PFPE/PFOEA copolymer infused with a Krytox 102 encapsulating liquid and immersed in water 812 for 3 days. The top row shows no replenishment during this time, while the bottom row shows replenishment with fresh, water-free encapsulating liquid once a day for three days. The active black material starts to degrade on day two without replenishment, whereas the same material is intact after three days when the encapsulation layer is replenished daily.

### A. Reduction of Water Absorption

FIGS. 28A-28B and 29A-29C show results from preliminary experiments indicating that a liquid overlayer substantially reduces water adsorption. FIG. 28A shows the deterioration of perovskite coated with a Teflon® film on the left-hand side, and FIG. 28B shows perovskite coated with a Teflon film infused with DuPont GPL 107 on the right-hand side. FIGS. 28A-28B show each coated perovskite before immersion in water, after full immersion in water for 10 minutes, and after full immersion in water for 2 hours. The oil infused Teflon film stabilized perovskite in water for 2 hours, corresponding to about a 20-fold improvement over perovskite encapsulated with dry Teflon. Perovskite encapsulated in dry Teflon underwent a color change after 5 minutes under water and reached an advanced state of decomposition at t=10 minutes in the water bath. In contrast, the perovskite coated with liquid-infused Teflon showed no change after 2 hours.

FIGS. 29A-29C show the effect of liquid viscosity for a crosslinked fluorinated polymer matrix used as an encapsulation layer of halide perovskite thin films. FIG. 29A shows a dry crosslinked fluorinated polymer matrix (fluorogel)-coated halide perovskite thin film immersed in water. FIG. 29B shows a low-viscosity oil-infused (DuPont Krytox GPL 102), crosslinked fluorinated polymer matrix (fluorogel)-coated halide perovskite thin film immersed in water. FIG. 29C shows a high-viscosity oil-infused (DuPont Krytox GPL 107), crosslinked fluorinated polymer matrix (fluorogel)-coated halide perovskite thin film immersed in water. Both fluorogels infused with oil, shown in FIGS. 29B-29C, showed reduced deterioration compared the fluorogel without oil, shown in FIG. 29A.

### B. Dye as an Experimental Model of Water Diffusion

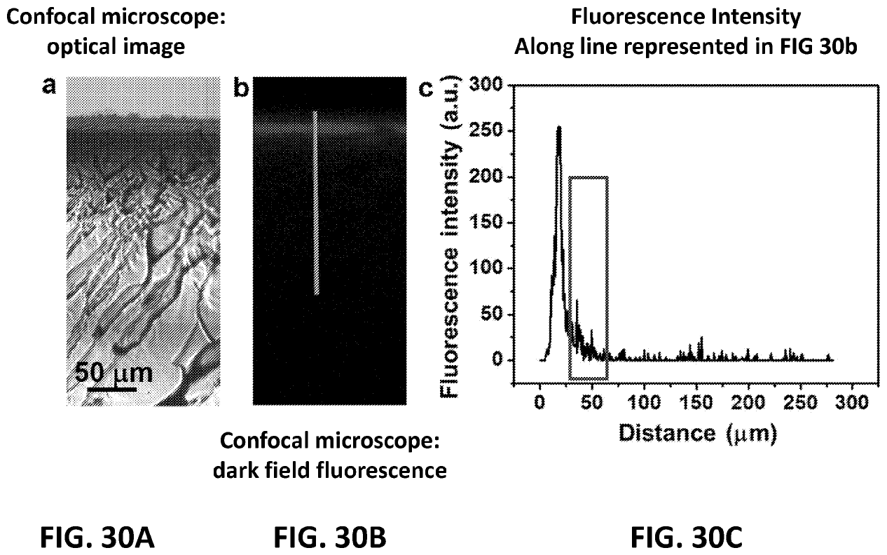

FIGS. 30A-30B show use of Rhodamine B dye as an experimental model for water diffusion. A charged dye molecule is analogous to a water cluster in terms of polarity and size, suggesting comparable adsorption and diffusion properties. The diffusivity of dye molecules was extrapolated by characterizing diffusion profiles using confocal microscopy. A dry crosslinked fluorinated matrix was immersed in the aqueous dye solution for 3 days. Both surface adsorption and bulk diffusion were observed using confocal microscopy. FIG. 30A shows a cross-sectional 2D confocal microscope optical image of dye distributions in a dry fluorogel. FIG. 30B shows a cross-sectional 2D confocal microscope dark-field fluorescent image of dye distributions near the surface in a dry fluorogel. FIG. 30C shows the fluorescence intensity profile as a function of film depth along a path corresponding to the vertical line in FIG. 30B. The box highlights the region where the dye has diffused. The dye diffused a distance of approximately 50 μm into the fluorogel.

It will be appreciated that while one or more particular materials or steps have been shown and described for purposes of explanation, the materials or steps can be varied in certain respects, or materials or steps can be combined, while still obtaining the desired outcome. For example, in some embodiments, a container can be combined with an infused polymer or porous material. Additionally, modifications to the disclosed embodiment and the invention as claimed are possible and within the scope of this disclosed invention.

1-115. (canceled)

116. A liquid-based encapsulation system comprising
an electronic material having a plurality of exposed surfaces; and
an encapsulating liquid disposed over an entirety of the plurality of exposed surfaces of the electronic material to prevent diffusion of water past the encapsulating liquid and to protect the electronic material from water.

117. The liquid-based encapsulation system of claim 116, further comprising a coating material infused with the encapsulating liquid.

118. The liquid-based encapsulation system of claim 117, wherein the coating material is a polymer.

119. The liquid-based encapsulation system of claim 118, wherein the polymer is crosslinked.

120. The liquid-based encapsulation system of claim 118, wherein the polymer is selected from the group consisting of fluoropolymers, butyl rubbers, silicones, polyethylene, polystyrene, polyvinyl chloride, and combinations thereof.

121. The liquid-based encapsulation system of claim 118, wherein the electronic material, the polymer, and the encapsulating liquid are disposed within a container,

122. The liquid-based encapsulation system of claim 121, wherein the container is flexible.

123. The liquid-based encapsulation system of claim 121, further comprising a water-removal unit fluidically connected to the container by an inlet and an outlet.

124. The liquid-based encapsulation system of any of claim 118, wherein the encapsulating liquid forms an overlayer over the polymer.

125. The liquid-based encapsulation system of claim 124, wherein the overlayer is slippery.

126. The liquid-based encapsulation system of claim 124, wherein the polymer and overlayer are transparent.

127. The liquid-based encapsulation system of claim 116, wherein the encapsulating liquid comprises a plurality of encapsulating liquids forming a multi-layered system.

128. The liquid-based encapsulation system of claim 117, wherein the coating material is a porous material.

129. The liquid-based encapsulation system of claim 128, wherein the porous material is selected from the group consisting of silica, titania, alumina, and combinations thereof.

130. The liquid-based encapsulation system of claim 116, wherein the electronic material is disposed within a container.

131. The liquid-based encapsulation system of claim 116, wherein the encapsulating liquid is selected from a group consisting of polyfluorinated oils, perfluorinated liquids, partially fluorinated liquids, hydrocarbons, organosilanes, silicone oils, mineral oils, plant oils, and combinations thereof.

132. The liquid-based encapsulation system of claim 116, wherein the electronic material is selected from a group consisting of photovoltaic cells, perovskite photovoltaic cells, integrated circuits, flexible circuits, and combinations thereof.

133. A method of replenishing an encapsulating liquid to a liquid-based encapsulation system comprising an electronic material and the encapsulating liquid forming an overlayer over the electronic material, the method comprising
introducing additional encapsulating liquid to the liquid-based encapsulation system.

134. The method of claim 133, wherein introducing additional encapsulating liquid occurs at periodic intervals.

135. The method of claim 133, wherein introducing additional encapsulating liquid occurs continuously.
